(19) United States
(12) Patent Application Publication
(10) Pub. No.: US 2023/0317734 A1
(43) Pub. Date: Oct. 5, 2023

(54) DISPLAY DEVICE

(71) Applicant: Samsung Display Co., LTD., Yongin-si (KR)

(72) Inventors: Yong Hee LEE, Suwon-si (KR); Jin Seon KWAK, Hwaseong-si (KR); Kyung Bae KIM, Seongnam-si (KR); Ji Hye LEE, Hwaseong-si (KR)

(73) Assignee: Samsung Display Co., LTD., Yongin-si (KR)

(21) Appl. No.: 18/093,493

(22) Filed: Jan. 5, 2023

(30) Foreign Application Priority Data
Mar. 30, 2022 (KR) 10-2022-0039747

(51) Int. Cl. H01L 27/12; H01L 25/16

(52) U.S. Cl. CPC H01L 27/124; H01L 25/167

(57) ABSTRACT

A display device comprising a display area in which pixels are disposed, each of the pixels comprising a first electrode and a second electrode; and light emitting elements, a first dummy pixel area disposed outside the display area and in which dummy pixels are disposed, each of the dummy pixels comprising the first electrode, the second electrode and the light emitting elements, and a second dummy pixel area surrounding the display area and the first dummy pixel area and in which dummy electrode lines and dummy electrode patterns are disposed, wherein the dummy electrode lines are spaced apart from each other and are electrically connected to the second electrodes of the dummy pixels, and the dummy electrode patterns are disposed between the dummy electrode lines and are spaced apart from the first electrodes of the dummy pixels.

### CROSS REFERENCE TO RELATED APPLICATION(S)

This application claims priority from Korean Patent Application No. 10-2022-0039747 filed on Mar. 30, 2022 in the Korean Intellectual Property Office, and all the benefits accruing therefrom under 35 U.S.C. 119, the contents of which in its entirety are herein incorporated by reference.

### BACKGROUND

### 1. Technical Field

The disclosure relates to a display device.

### 2. Description of the Related Art

Display devices are becoming increasingly important with the development of multimedia. Accordingly, various types of display devices such as organic light emitting displays (OLEDs) and liquid crystal displays (LCDs) are being used.

As a device for displaying an image of a display device, there is a self-luminous display device including a light emitting element. The self-luminous display device may be an organic light emitting display using an organic material as a light emitting material as a light emitting element or an inorganic light emitting display using an inorganic material as a light emitting material.

### SUMMARY

Aspects of the disclosure provide a display device including a dummy pixel area in which dummy pixels and dummy electrodes having a similar structure to electrodes of pixels disposed in a display area are disposed.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment of the disclosure, a display device comprising a display area in which pixels are disposed, each of the pixels comprising a first electrode and a second electrode extending in a first direction and spaced apart from each other in a second direction, and light emitting elements disposed on the first electrode and the second electrode, a first dummy pixel area disposed outside the display area and in which dummy pixels are disposed, each of the dummy pixels comprising the first electrode, the second electrode and the light emitting elements, and a second dummy pixel area surrounding the display area and the first dummy pixel area and in which dummy electrode lines and dummy electrode patterns are disposed, wherein the dummy electrode lines extend in the first direction, are spaced apart from each other in the second direction and are electrically connected to the second electrodes of the dummy pixels, and the dummy electrode patterns extend in the first direction, are disposed between the dummy electrode lines and are spaced apart from the first electrodes of the dummy pixels in the first direction.

The second dummy pixel area may comprise a first area disposed on a side of the display area in the first direction, a second area disposed on each of sides of the display area in the second direction, and a third area disposed on another side of the display area in the first direction, and the first dummy electrode lines and the first dummy electrode patterns may be disposed in the first area and the third area.

Each of the first dummy electrode patterns disposed in the first area and the third area may be electrically connected to any adjacent one of the dummy electrode lines.

The dummy electrode lines disposed in the third area may be directly connected to the second electrodes disposed in the pixels of the display area.

The dummy electrode patterns may comprise second dummy electrode patterns disposed in the second area on sides of the first area and the third area in the second direction and third dummy patterns disposed in the second area on sides of the display area in the second direction and spaced apart from each other in the first direction.

The third dummy electrode patterns may be respectively electrically connected to the second electrodes of the dummy pixels disposed in the first dummy pixel area.

The second dummy electrode patterns may be respectively electrically connected to the dummy electrode lines disposed in outermost portions of the first area and the third area.

The first dummy pixel area may be disposed between the display area and the first area and the second area of the second dummy pixel area.

The third area of the second dummy pixel area may be in contact with the display area.

Lengths of the dummy electrode lines and the first dummy electrode patterns in the first direction in the third area may be greater than lengths of the dummy electrode lines and the first dummy electrode patterns in the first direction in the first area.

The second electrodes disposed in the first dummy pixel area may be directly connected to the second electrodes of the pixels disposed in the display area, and the first electrodes disposed in the first dummy pixel area may be spaced apart from the first electrodes of the pixels disposed in the display area.

The light emitting elements may be not disposed in the second dummy pixel area.

The display device may comprise a first connection electrode disposed on the first electrode of each of the pixels and the dummy pixels and electrically contacting the light emitting elements, and a second connection electrode disposed on the second electrode of each of the pixels and the dummy pixels and electrically contacting the light emitting elements, wherein the first connection electrode and the second connection electrode of each pixel may electrically contact the first electrode and the second electrode, respectively.

The first connection electrode and the second connection electrode disposed in each of the dummy pixels may do not electrically contact the first electrode and the second electrode, respectively.

The first connection electrode and the second connection electrode may be not disposed in the second dummy pixel area.

The first and second electrodes, the dummy electrode lines, and the dummy electrode patterns may be disposed on a same layer.

According to an embodiment of the disclosure, a display device comprising a display area in which pixels are disposed, each of the pixels comprising a first electrode and a second electrode extending in a first direction and spaced apart from each other in a second direction, and light emitting elements disposed on the first electrode and the second electrode, a first dummy pixel area disposed outside the display area and in which dummy pixels are disposed, each of the dummy pixels comprising the first electrode, the second electrode and the light emitting elements, and a second dummy pixel area surrounding the display area and the first dummy pixel area and in which dummy electrode lines and dummy electrode patterns are disposed, wherein the second dummy pixel area comprises a first area disposed on a side of the display area in the first direction, a second area disposed on each of sides of the display area in the second direction and a third area disposed on another side of the display area in the first direction, the dummy electrode lines comprise first dummy electrode lines disposed in the first area and the third area and a second dummy electrode line disposed in the second area, and the dummy electrode patterns comprise a first dummy electrode pattern disposed between the first dummy electrode lines in the first area and the third area and electrically connected to each of adjacent ones of the first dummy electrode lines.

The first dummy electrode lines may be spaced apart from the second electrodes of the dummy pixels in the first direction, and the second dummy electrode line may be directly connected to the second electrodes of the dummy pixels disposed in an outermost portion of the first dummy pixel area in the second direction.

The second dummy electrode line may be directly connected to the first dummy electrode lines disposed in outermost portions of the first area and the third area in the second direction.

The light emitting elements may be not disposed in the second dummy pixel area.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic plan view of a display device according to an embodiment;

FIG. 2 is a schematic plan view illustrating the arrangement of wirings included in the display device according to the embodiment;

FIGS. 3 and 4 are schematic diagrams of equivalent circuits of a subpixel of the display device according to the embodiment;

FIG. 5 is a schematic plan view of a pixel of the display device according to the embodiment;

FIG. 6 is a schematic cross-sectional view taken along line N1-N1′ of FIG. 5;

FIG. 7 is a schematic cross-sectional view taken along line N2-N2′ of FIG. 5;

FIG. 8 is a schematic cross-sectional view taken along line N3-N3′ of FIG. 5;

FIG. 9 is a schematic view of a light emitting element according to an embodiment;

FIG. 10 illustrates the schematic arrangement of a display area and dummy pixel areas of the display device according to the embodiment;

FIG. 11 is a schematic plan view of portion Q1 of FIG. 10;

FIG. 12 is a schematic plan view of portion Q2 of FIG. 10;

FIG. 13 is a schematic plan view illustrating the arrangement of dummy electrodes in a first area of a second dummy pixel area of the display device according to the embodiment;

FIG. 14 is a schematic plan view illustrating the arrangement of dummy electrodes in a second area of the second dummy pixel area of the display device according to the embodiment;

FIG. 15 is a schematic plan view illustrating a portion in which pixel circuit units are disposed in the display area and a dummy pixel area of the display device according to the embodiment;

FIG. 16 is a schematic cross-sectional view of the first area of the second dummy pixel area according to an embodiment;

FIG. 17 is a schematic cross-sectional view of a first area of a second dummy pixel area according to an embodiment; and

FIG. 18 is a schematic plan view illustrating dummy electrode lines in a dummy pixel area of a display device according to an embodiment.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be more thorough and complete, and will convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. The same reference numbers indicate the same components throughout the specification.

It will be understood that, although the terms “first,” “second,” and the like may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Spatially relative terms, such as “beneath,” “below,” “under,” “lower,” “on,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments will be described with reference to the accompanying drawings.

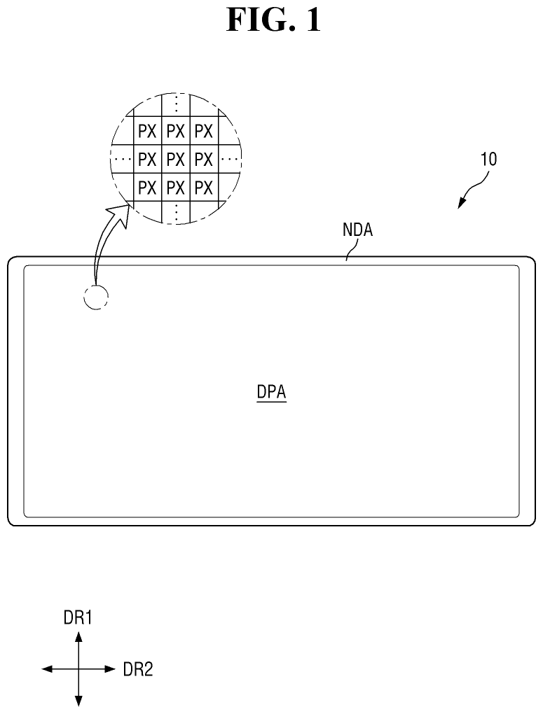

FIG. 1 is a schematic plan view of a display device 10 according to an embodiment.

Referring to FIG. 1, the display device 10 displays moving images or still images. The display device 10 may refer to any electronic device that provides a display screen. Examples of the display device 10 may include televisions, laptop computers, monitors. billboards, Internet of things (IoT) devices, mobile phones, smartphones, tablet personal computers (PCs), electronic watches, smartwatches, watch phones, head-mounted displays, mobile communication terminals, electronic notebooks, e-book readers, portable multimedia players (PMPs), navigation devices, game machines, digital cameras and camcorders, all of which provide a display screen.

The display device 10 includes a display panel that provides a display screen. Examples of the display panel include inorganic light emitting diode display panels, organic light emitting display panels, quantum dot light emitting display panels, plasma display panels, and field emission display panels. A case where an inorganic light emitting diode display panel is applied as an example of the display panel will be described below, but the disclosure is not limited to this case, and other display panels can also be applied as long as the same technical spirit is applicable.

The shape of the display device 10 can be variously modified. For example, the display device 10 may have various shapes such as a horizontally long rectangle, a vertically long rectangle, a square, a quadrilateral with rounded corners (vertices), other polygons, or a circle. The shape of a display area DPA of the display device 10 may also be similar to the overall shape of the display device 10. FIG. 1 illustrates the display device 10 shaped like a rectangle that is long in a second direction DR2.

The display device 10 may include the display area DPA and a non-display area NDA. The display area DPA may be an area where an image can be displayed, and the non-display area NDA may be an area where no image is displayed. The display area DPA may also be referred to as an active area, and the non-display area NDA may also be referred to as an inactive area. The display area DPA may generally occupy a center of the display device 10.

The display area DPA may include pixels PX. The pixels PX may be arranged in a matrix direction. Each of the pixels PX may be rectangular or square in a plan view. However, the disclosure is not limited thereto, and each of the pixels PX may also have a rhombic planar shape having each side inclined with respect to a direction. The pixels PX may be arranged in a stripe or island type. Each of the pixels PX may include one or more light emitting elements which emit light of a specific wavelength band to display a specific color.

The non-display area NDA may be located around the display area DPA. The non-display area NDA may entirely or partially surround the display area DPA. The display area DPA may be rectangular, and the non-display area NDA may be disposed adjacent to four sides of the display area DPA. The non-display area NDA may form a bezel of the display device 10. In each non-display area NDA, wirings or circuit drivers included in the display device 10 may be located, or external devices may be mounted.

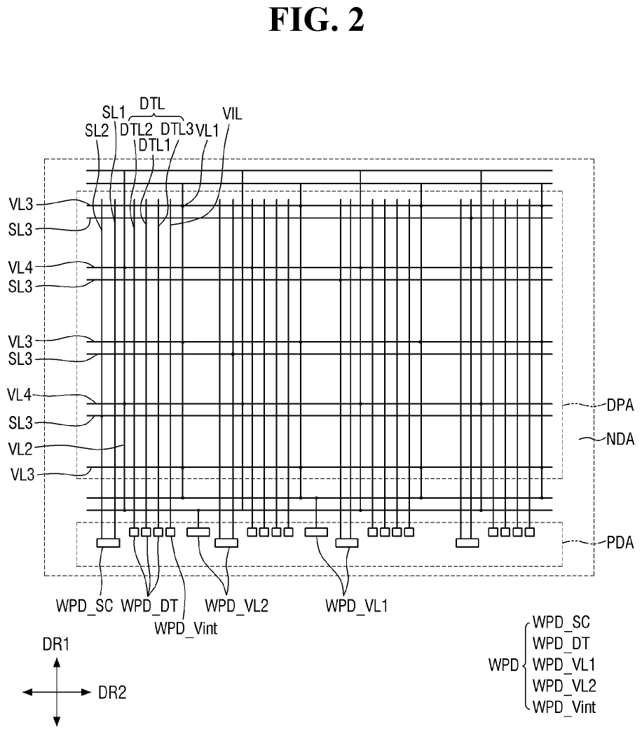

FIG. 2 is a schematic plan view illustrating the arrangement of wirings included in the display device 10 according to the embodiment.

Referring to FIG. 2, the display device 10 may include wirings. The display device 10 may include scan lines SL1 to SL3, data lines DTL (DTL1 to DTL3), initialization voltage wirings VIL, and voltage wirings VL (VL1 to VL4). Although not illustrated in the drawing, other wirings may be further disposed in the display device 10. The wirings may include wirings formed as (or made of) a first conductive layer and extending in a first direction DR1 and wirings formed as a third conductive layer and extending in the second direction DR2. However, the directions in which the wirings extend are not limited thereto.

First scan lines SL1 and second scan lines SL2 may extend in the first direction DR1. A first scan line SL1 and a second scan line SL2 in each pair may be disposed adjacent to each other and may be spaced apart from other first scan lines SL1 and other second scan lines SL2 in the second direction DR2. The first and second scan lines SL1 and SL2 may be connected to each scan wiring pad WPD_SC connected to a scan driver (not illustrated). The first scan lines SL1 and the second scan lines SL2 may extend from a pad area PDA disposed in the non-display area NDA to the display area DPA.

Each third scan line SL3 may extend in the second direction DR2 and may be spaced apart from other third scan lines SL3 in the first direction DR1. A third scan line SL3 may be connected to one or more first scan lines SL1 or one or more second scan lines SL2. The scan lines SL may have a mesh structure in the entire display area DPA, but the disclosure is not limited thereto.

The data lines DTL may extend in the first direction DR1. The data lines DTL may include first data lines DTL1, second data lines DTL2, and third data lines DTL3. Each of the first to third data lines DTL1 to DTL3 may form a group and may be disposed adjacent to each other. The data lines DTL1 to DTL3 may extend from the pad area PDA disposed in the non-display area NDA to the display area DPA. However, the disclosure is not limited thereto, and the data lines DTL may also be spaced apart from each other at equal intervals between first and second voltage wirings VL1 and VL2 to be described below.

The initialization voltage wirings VIL may extend in the first direction DR1. Each of the initialization voltage wirings VIL may be disposed between the data lines DTL and a first voltage wiring VL1. The initialization voltage wirings VIL may extend from the pad area PDA disposed in the non-display area NDA to the display area DPA.

The first voltage wirings VL1 and the second voltage wirings VL2 extend in the first direction DR1, and third voltage wirings VL3 and fourth voltage wirings VL4 extend in the second direction DR2. The first voltage wirings VL1 and the second voltage wirings VL2 may be alternately disposed in the second direction DR2, and the third voltage wirings VL3 and the fourth voltage wirings VL4 may be alternately disposed in the first direction DR1. The first voltage wirings VL1 and the second voltage wirings VL2 may extend in the first direction DR1 to cross the display area DPA. Among the third voltage wirings VL3 and the fourth voltage wirings VL4, some wirings may be disposed in the display area DPA, and other wirings may be disposed in the non-display area NDA located on sides of the display area DPA in the first direction DR1. The voltage wirings VL may have a mesh structure in the entire display area DPA. However, the disclosure is not limited thereto.

The first scan lines SL1, the second scan lines SL2, the data lines DTL, the initialization voltage wirings VIL, the first voltage wirings VL1, and the second voltage wirings VL2 may be electrically connected to at least one wiring pad WPD. For example, the first and second scan lines SL1 and SL2 are connected to each scan wiring pad WPD_SC disposed in the pad area PDA, and the data lines DTL are connected to different data wiring pads WPD DT, respectively. Each of the initialization voltage wirings VIL is connected to an initialization wiring pad WPD_Vint, the first voltage wirings VL1 are connected to a first voltage wiring pad WPD_VL1, and the second voltage wirings VL2 are connected to a second voltage wiring pad WPD_VL2. An external device may be mounted on the wiring pads WPD.

Each pixel PX or subpixel SPXn (where n is an integer of 1 to 3) of the display device 10 includes a pixel driving circuit. The above-described wirings may transmit a driving signal to each pixel driving circuit while passing through or around each pixel PX. The pixel driving circuit may include a transistor and a capacitor. According to an embodiment, each subpixel SPXn of the display device 10 may have a 3T1C structure in which the pixel driving circuit includes three transistors and a capacitor. Although the pixel driving circuit will be described below using the 3T1C structure as an example, the disclosure is not limited thereto, and other various modified structures such as a 2T1C structure, a 7T1C structure, and a 6T1C structure are also applicable.

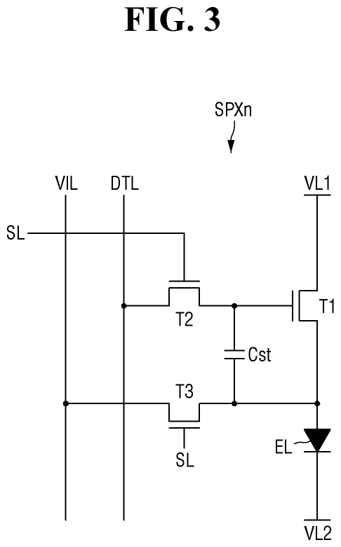

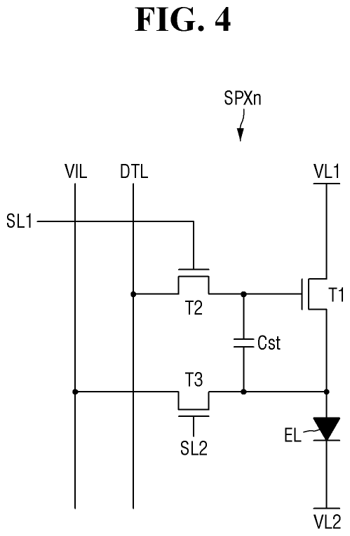

FIGS. 3 and 4 are schematic diagrams of equivalent circuits of a subpixel SPXn of the display device 10 according to the embodiment.

Referring to FIG. 3, each subpixel SPXn of the display device 10 according to the embodiment includes three transistors T1 to T3 and a storage capacitor Cst in addition to a light emitting diode EL.

The light emitting diode EL emits light according to a current supplied through a first transistor T1. The light emitting diode EL includes a first electrode, a second electrode, and at least one light emitting element disposed between them. The light emitting element may emit light of a specific wavelength band in response to electrical signals received from the first electrode and the second electrode.

A first end of the light emitting diode EL may be connected to a source electrode of the first transistor T1, and a second end of the light emitting diode EL may be connected to a second voltage wiring VL2 to which a low potential voltage (hereinafter, referred to as a second power supply voltage) lower than a high potential voltage (hereinafter, referred to as a first power supply voltage) of a first voltage wiring VL1 is supplied.

The first transistor T1 adjusts a current flowing from the first voltage wiring VL1, to which the first power supply voltage is supplied, to the light emitting diode EL according to a voltage difference between a gate electrode and the source electrode. For example, the first transistor T1 may be a driving transistor for driving the light emitting diode EL. The first transistor T1 may have the gate electrode connected to a source electrode of a second transistor T2, the source electrode connected to a first electrode of the light emitting diode EL, and a drain electrode connected to the first voltage wiring VL1 to which the first power supply voltage is applied.

The second transistor T2 is turned on by a scan signal of a scan line SL to connect a data line DTL to the gate electrode of the first transistor T1. The second transistor T2 may have a gate electrode connected to the scan line SL, the source electrode connected to the gate electrode of the first transistor T1, and a drain electrode connected to the data line DTL.

A third transistor T3 is turned on by the scan signal of the scan line SL to connect an initialization voltage wiring VIL to the first end of the light emitting diode EL. The third transistor T3 may have a gate electrode connected to the scan line SL, a drain electrode connected to the initialization voltage wiring VIL, and a source electrode connected to the first end of the light emitting diode EL or the source electrode of the first transistor T1.

In an embodiment, the source electrode and the drain electrode of each of the transistors T1 to T3 are not limited to the above description, and the opposite may also be the case. Each of the transistors T1 to T3 may be formed as a thin-film transistor. Although FIG. 3 illustrates that each of the transistors T1 to T3 is formed as an N-type metal oxide semiconductor field effect transistor (MOSFET), the disclosure is not limited thereto. For example, each of the transistors T1 to T3 may also be formed as a P-type MOSFET, or some of the transistors T1 to T3 may be formed as N-type MOSFETs, and others thereof may be formed as a P-type MOSFETs.

The storage capacitor Cst is formed between the gate electrode and the source electrode of the first transistor T1. The storage capacitor Cst stores a difference between a gate voltage and a source voltage of the first transistor T1.

In the embodiment of FIG. 3, the gate electrode of the second transistor T2 and the gate electrode of the third transistor T3 may be connected to a same scan line SL. The second transistor T2 and the third transistor T3 may be turned on by the scan signal transmitted from a same scan line. However, the disclosure is not limited thereto.

Referring to FIG. 4, the gate electrodes of the second transistor T2 and the third transistor T3 may be connected to different scan lines SL1 and SL2. For example, the gate electrode of the second transistor T2 may be electrically connected to a first scan line SL1, and

the gate electrode of the third transistor T3 may be electrically connected to a second scan line SL2. The second transistor T2 and the third transistor T3 may be simultaneously turned on by scan signals transmitted from different scan lines.

The structure of a pixel PX of the display device 10 according to the embodiment will now be described in detail with further reference to other drawings.

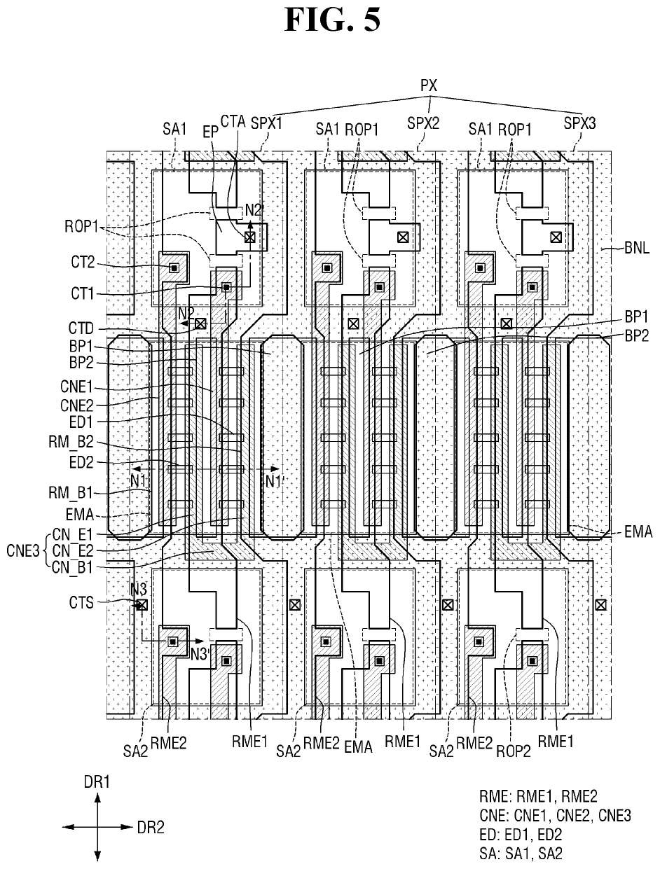

FIG. 5 is a schematic plan view of a pixel PX of the display device 10 according to the embodiment.

FIG. 5 illustrates the planar arrangement of electrodes RME (RME1 and RME2), barrier walls BP1 and BP2, a bank layer BNL, light emitting elements ED (ED1 and ED2), and connection electrodes CNE (CNE1 to CNE3) in a pixel PX of the display device 10.

Referring to FIG. 5, each of the pixels PX of the display device 10 may include subpixels SPXn. For example, a pixel PX may include a first subpixel SPX1, a second subpixel SPX2, and a third subpixel SPX3. The first subpixel SPX1 may emit light of a first color, the second subpixel SPX2 may emit light of a second color, and the third subpixel SPX3 may emit light of a third color. For example, the first color may be blue, the second color may be green, and the third color may be red. However, the disclosure is not limited thereto, and the subpixels SPXn may also emit light of a same color. In an embodiment, the subpixels SPXn may emit blue light. Although FIG. 5 illustrates that a pixel PX includes three subpixels SPXn, the disclosure is not limited thereto, and the pixel PX may also include a greater number of subpixels SPXn.

Each subpixel SPXn of the display device 10 may include an emission area EMA and a non-emission area. The emission area EMA may be an area in which the light emitting elements ED are disposed to emit light of a specific wavelength band. The non-emission area may be an area in which the light emitting elements ED are not disposed and from which no light is output because light emitted from the light emitting elements ED does not reach this area.

The emission area EMA may include an area in which the light emitting elements ED are disposed and an area which is adjacent to the light emitting elements ED and from which light emitted from the light emitting elements ED is output. For example, the emission area EMA may also include an area from which light emitted from the light emitting elements ED is output after being reflected or refracted by other members. Light emitting elements ED may be disposed in each subpixel SPXn, and an area where the light emitting elements ED are located and an area adjacent to this area may form the emission area EMA.

Although FIG. 5 illustrates that the respective emission areas EMA of the subpixels SPXn have substantially a same area, the disclosure is not limited thereto. In some embodiments, the emission area EMA of each subpixel SPXn may have a different area according to the color or wavelength band of light emitted from the light emitting elements ED disposed in the subpixel SPXn.

Each subpixel SPXn may further include sub-areas SA1 and SA2 disposed in the non-emission area. The sub-areas SA1 and SA2 may include a first sub-area SA1 disposed on an upper side of the emission area EMA which is a side in the first direction DR1 and a second sub-area SA2 disposed on a lower side of the emission area EMA which is the other side in the first direction DR1. The emission area EMA and the sub-areas SA1 and SA2 may be alternately arranged in the first direction DR1 according to the arrangement of the pixels PX and the subpixels SPXn, and the first sub-area SA1 or the second sub-area SA2 may be disposed between different emission areas EMA spaced apart from each other in the first direction DR1. For example, emission areas EMA may be repeatedly arranged in the first direction DR1 with the first sub-area SA1 or the second sub-area SA2 interposed between them. Emission areas EMA, first sub-areas SA1, and second sub-areas SA2 may each be repeatedly arranged in the second direction DR2. The first and second sub-areas SA1 and SA2 may be areas distinguished from each other by the arrangement of wiring connection electrodes EP and the electrodes RME which will be described below. However, the disclosure is not limited thereto, and the arrangement of the emission areas EMA and the sub-areas SA1 and SA2 in pixels PX may also be different from that in FIG. 5.

Each of the first and second sub-areas SA1 and SA2 may be an area shared by subpixels SPXn adjacent to each other in the first direction DR1. The subpixels SPXn illustrated in FIG. 5 may be subpixels having the first sub-area SA1 disposed above the emission area EMA, and subpixels SPXn adjacent to the above subpixels SPXn in the first direction DR1 may be subpixels having the second sub-area SA2 disposed above the emission area EMA.

Light may not exit from the sub-areas SA1 and SA2 because the light emitting elements ED are not disposed in the sub-areas SA1 and SA2, but a portion of each of the electrodes RME disposed in each subpixel SPXn may be disposed in the sub-areas SA1 and SA2. The electrodes RME disposed in different subpixels SPXn may be separated from each other in separation portions ROP1 and ROP2 of the sub-areas SA1 and SA2.

The display device 10 may include the electrodes RME (RME1 and RME2), the barrier walls BP1 and BP2, the bank layer BNL, the light emitting elements ED, and the connection electrodes CNE (CNE1 to CNE3).

The barrier walls BP1 and BP2 may be disposed in the emission area EMA of each subpixel SPXn. The barrier walls BP1 and BP2 may generally extend in the first direction DR1 and may be spaced apart from each other in the second direction DR2.

For example, the barrier walls BP1 and BP2 may include first and second barrier walls BP1 and BP2 spaced apart from each other in the second direction DR2 in the emission area EMA of each subpixel SPXn. The first barrier wall BP1 may be disposed in a center of the emission area EMA, and the second barrier walls BP2 may be spaced apart from each other with the first barrier wall BP1 interposed between them. The first and second barrier walls BP1 and BP2 may be alternately arranged in the second direction DR2 and may be disposed as island-shaped patterns in the display area DPA. Light emitting elements ED may be disposed between the first and second barrier walls BP1 and BP2.

A width of each of the second barrier walls BP2 measured in the second direction DR2 may be greater than a width of the first barrier wall BP1. While the first barrier wall BP1 is disposed in the emission area EMA of each subpixel SPXn, each of the second barrier walls BP2 may be disposed over the emission areas EMA of two subpixels SPXn adjacent to each other in the second direction DR2. Each of the second barrier walls BP2 may be disposed at a boundary between subpixels SPXn adjacent to each other in the second direction DR2 and may overlap (e.g., in a view or a direction) the bank layer BNL to be described below. However, the disclosure is not limited thereto, and the first and second barrier walls BP1 and BP2 may also have a same width.

The barrier walls BP1 and BP2 may have a same length in the first direction DR1 and may be longer in the first direction DR1 than the emission area EMA surrounded by the bank layer BNL. The barrier walls BP1 and BP2 may overlap portions of the bank layer BNL which extend in the second direction DR2. However, the disclosure is not limited thereto, and the barrier walls BP1 and BP2 may also be integrated with the bank layer BNL or may be spaced apart from the portions of the bank layer BNL which extend in the second direction DR2. The length of each of the barrier walls BP1 and BP2 in the first direction DR1 may be equal to or smaller than the length, in the first direction DR1, of the emission area EMA surrounded by the bank layer BNL.

The electrodes RME1 and RME2 may extend in a direction and may be disposed in each subpixel SPXn. The electrodes RME1 and RME2 may extend in the first direction DR1 to lie in the emission area EMA and the sub-areas SA1 and SA2 of each subpixel SPXn and may be spaced apart from each other in the second direction DR2. The electrodes RME1 and RME2 may be electrically connected to the light emitting elements ED to be described below. However, the disclosure is not limited thereto, and the electrodes RME may also not be electrically connected to the light emitting elements ED.

The display device 10 may include a first electrode RME1 disposed in the center of each subpixel SPXn and second electrodes RME2, each being disposed over different subpixels SPXn. The first and second electrodes RME1 and RME2 may generally extend in the first direction DR1, but their portions disposed in the emission area EMA may have different shapes. The first electrode RME1 may be disposed adjacent to the center of each subpixel SPXn and may be disposed over the emission area EMA and the sub-areas SA1 and SA2. Each of the second electrodes RME2 may be spaced apart from the first electrode RME1 in the second direction DR2 in the emission area EMA and may be disposed over subpixels SPXn. The first and second electrodes RME1 and RME2 may generally extend in the first direction DR1 but may have different lengths in the first direction DR1, and their portions disposed in the emission area EMA may have different shapes.

The first electrode RME1 may be disposed in the center of each subpixel SPXn, and a portion thereof disposed in the emission area EMA may be disposed on the first barrier wall BP1. The first electrode RME1 may extend in the first direction DR1 from the first sub-area SA1 to the second sub-area SA2. A width of the first electrode RME1 measured in the second direction DR2 may vary according to position, and at least a portion thereof overlapping the first barrier wall BP1 in the emission area EMA may have a greater width than the first barrier wall BP1.

Each of the second electrodes RME2 may include a portion extending in the first direction DR1 and portions branching from the above portion in the emission area EMA. In an embodiment, each of the second electrodes RME2 may include an electrode stem portion RM_S extending in the first direction DR1 and electrode branch portions RM_B1 and RM_B2 branching from the electrode stem portion RM_S, bending in the second direction DR2, and extending in the first direction DR1. The electrode stem portion RM_S may overlap a portion of the bank layer BNL which extends in the first direction DR1 and may be disposed on a side of a sub-area SA in the second direction DR2. The electrode branch portions RM_B1 and RM_B2 may branch from the electrode stem portion RM_S disposed in a portion of the bank layer BNL which extends in the first direction DR1 and may be bent to sides in the second direction DR2. The electrode branch portions RM_B1 and RM_B2 may extend across the emission area EMA in the first direction DR1 and may be bent again to be connected to the electrode stem portion RM_S. For example, the electrode branch portions RM_B1 and RM_B2 of each of the second electrodes RME2 may branch off on the upper side of the emission area EMA of any one subpixel SPXn and may be connected to each other again on the lower side of the emission area EMA.

Each of the second electrodes RME2 may include a first electrode branch portion RM_B1 disposed on a left side of the first electrode RME1 and a second electrode branch portion RM_B2 disposed on a right side of the first electrode RME1. The electrode branch portions RM_B1 and RM_B2 included in a second electrode RME2 may be respectively disposed in the emission areas EMA of subpixels SPXn neighboring each other in the second direction DR2, and the electrode branch portions RM_B1 and RM_B2 of different second electrodes RME2 may be disposed in a subpixel SPXn. The first electrode branch portion RM_B1 of a second electrode RME2 may be disposed on the left side of the first electrode RME1, and the second electrode branch portion RM_B2 of another second electrode RME2 may be disposed on the right side of the first electrode RME1.

Each of the electrode branch portions RM_B1 and RM_B2 of each second electrode RME2 may overlap a side of a second barrier wall BP2. The first electrode branch portion RM_B1 may partially overlap a second barrier wall BP2 disposed on a left side of the first barrier wall BP1, and the second electrode branch portion RM_B2 may partially overlap a second barrier wall BP2 disposed on a right side of the first barrier wall BP1. Sides of the first electrode RME1 may be spaced apart from different electrode branch portions RM_B1 and RM_B2 of different second electrodes RME2 to face them, and a distance between the first electrode RME1 and each of the electrode branch portions RM_B1 and RM_B2 may be smaller than a distance between different barrier walls BP1 and BP2.

The width of the first electrode RME1 measured in the second direction DR2 may be greater than widths of the electrode stem portion RM_S and the electrode branch portions RM_B1 and RM_B2 of each second electrode RME2. The first electrode RME1 may have a greater width than the first barrier wall BP1 to overlap sides of the first barrier wall BP1. On the other hand, each second electrode RME2 may have a relatively small width so that each of the electrode branch portions RM_B1 and RM_B2 overlaps only a side of a second barrier wall BP2.

The first electrode RME1 may extend to a first separation portion ROP1 of the first sub-area SA1 and a second separation portion ROP2 of a second sub-area SA2, but the second electrodes RME2 may not be separated in the sub-areas SA1 and SA2. A second electrode RME2 may extend in the first direction DR1 and may branch off near the emission area EMA of each subpixel SPXn. The first electrode RME1 may be disposed between the separation portions ROP1 and ROP2 disposed in different sub-areas SA1 and SA2 of each sub-pixel SPXn and may be disposed across the emission area EMA.

The display device 10 may include a wiring connection electrode EP disposed in the first sub-area SA1 among sub-areas SA1 and SA2 of each subpixel SPXn and disposed between the first electrodes RME1 of different subpixels SPXn. The wiring connection electrode EP may not be disposed in the second sub-area SA2 of each subpixel SPXn, and the first electrodes RME1 of different subpixels SPXn adjacent to each other in the first direction DR1 may be spaced apart from each other in the second sub-area SA2. In the pixel PX illustrated in FIG. 5 among subpixels SPXn, the first sub-area SA1 in which the wiring connection electrode EP is disposed may be disposed above the emission area EMA, and the second sub-area SA2 may be disposed below the emission area EMA. On the other hand, in a pixel PX adjacent to the pixel PX of FIG. 5 in the first direction DR1, the first sub-area SA1 in which the wiring connection electrode EP is disposed may be disposed below the emission area EMA, and the second sub area SA2 may be disposed above the emission area EMA.

The first electrode RME1 may be spaced apart from the wiring connection electrode EP with a first separation portion ROP1 interposed between them in the first sub-area SA1. Two first separation portions ROP1 may be disposed in the first sub-area SA1. The wiring connection electrode EP may be spaced apart from the first electrode RME1 disposed in a corresponding subpixel SPXn with a lower first separation portion ROP1 interposed between them and may be spaced apart from the first electrode RME1 disposed in another subpixel SPXn with an upper first separation portion ROP1 interposed between them. In the second sub-area SA2, a second separation portion ROP2 may be disposed, and different first electrodes RME1 may be spaced apart from each other in the first direction DR1.

The bank layer BNL may surround the subpixels SPXn, the emission areas EMA, and the sub-areas SA1 and SA2. The bank layer BNL may be disposed between the subpixels SPXn adjacent to each other in the first direction DR1 and the second direction DR2 and also may be disposed between the emission areas EMA and the sub-areas SA1 and SA2. The subpixels SPXn, the emission areas EMA and the sub-areas SA1 and SA2 of the display device 10 may be areas separated by the bank layer BNL. Distances between the subpixels SPXn, the emission areas EMA, and the sub-areas SA1 and SA2 may vary according to a width of the bank layer BNL.

The light emitting elements ED may be disposed in the emission area EMA. The light emitting elements ED may be disposed between the barrier walls BP1 and BP2 and may be spaced apart from each other in the first direction DR1 or the second direction DR2. In an embodiment, the light emitting elements ED may extend in a direction, and ends of the light emitting elements ED may be disposed on different electrodes RME, respectively. A length of each light emitting element ED may be greater than a distance between the electrodes RME spaced apart from each other in the second direction DR2. The direction in which the light emitting elements ED extend may be substantially perpendicular to the first direction DR1 in which the electrodes RME extend. However, the disclosure is not limited thereto, and the direction in which the light emitting elements ED extend may also be the second direction DR2 or a direction oblique to the second direction DR2.

The light emitting elements ED may include first light emitting elements ED1 having ends disposed on the first electrode RME1 and any one of the second electrodes RME2 and second light emitting elements ED2 having ends disposed on the first electrode RME1 and the other second electrode RME2. In the first subpixel SPX1, the first light emitting elements ED1 may be disposed on the first electrode RME1 and the second electrode branch portion RM_B2 of a second electrode RME2, and the second light emitting elements ED2 may be disposed on the first electrode RME1 and the first electrode branch portion RM_B1 of another second electrode RME2. The first light emitting elements ED1 may be disposed on the right side of the first electrode RME1, and the second light emitting elements ED2 may be disposed on the left side of the first electrode RME1. The first light emitting elements ED1 and the second light emitting elements ED2 may be disposed on the first and second electrodes RME1 and RME2 but may be disposed on different second electrodes RME2.

The connection electrodes CNE (CNE1 to CNE3) may be disposed on the electrodes RME and the barrier walls BP1 and BP2. The connection electrodes CNE may extend in a direction and may be spaced apart from each other. Each of the connection electrodes CNE may contact the light emitting elements ED and may be electrically connected to a conductive layer under the connection electrode CNE.

The connection electrodes CNE may include a first connection electrode CNE1, a second connection electrode CNE2, and a third connection electrode CNE3 disposed in each subpixel SPXn.

The first connection electrode CNE1 may extend in the first direction DR1 and may be disposed on the first electrode RME1. The first connection electrode CNE1 may overlap the first barrier wall BP1 and the first electrode RME1 and may extend in the first direction DR1 from the emission area EMA to the first sub-area SA1 located above the emission area EMA. The first connection electrode CNE1 may contact the first electrode RME1 through a first contact hole CT1 on the first electrode RME1 in the first sub-area SA1.

The second connection electrode CNE2 may be spaced apart from the first connection electrode CNE1 in the second direction DR2, may extend in the first direction DR1, and may be disposed on a second electrode RME2. The second connection electrode CNE2 may be disposed on the second electrode branch portion RM_B2 of the second electrode RME2 disposed on the left side of the first electrode RME1. The second connection electrode CNE2 may overlap a second barrier wall BP2 and the second electrode branch portion RM_B2 of the second electrode RME2 and may extend in the first direction DR1 from the emission area EMA to the first sub-area SA1 located above the emission area EMA. The second connection electrode CNE2 may contact the second electrode RME2 through a second contact hole CT2 formed on the second electrode RME2 in the first sub-area SA1.

The third connection electrode CNE3 may include extension portions CN_E1 and CN_E2 extending in the first direction DR1 and a first connection portion CN_B1 connecting the extension portions CN_E1 and CN_E2. A first extension portion CN_E1 may face the first connection electrode CNE1 in the emission area EMA and may be disposed on a second electrode RME2. In the first subpixel SPX1, the first extension portion CN_E1 may be disposed on the second electrode branch portion RM_B2 of the second electrode RME2. A second extension portion CN_E2 may face the second connection electrode CNE2 in the emission area EMA and may be disposed on the first electrode RME1. The first connection portion CN_B1 may extend in the second direction DR2 on the bank layer BNL disposed below the emission area EMA and may connect the first extension portion CN_E1 and the second extension portion CN_E2. The third connection electrode CNE3 may be disposed in the emission area EMA and on the bank layer BNL and may not be directly connected to the electrodes RME. The second electrode RME2 disposed under the first extension portion CN_E1 may be electrically connected to a second voltage wiring VL2, but the second power supply voltage applied to the second electrode RME2 may not be transferred to the third connection electrode CNE3.

As will be described below, ends of each light emitting element ED in the extending direction may be distinguished from each other, and the light emitting elements ED may be connected to each other in series through the connection electrodes CNE that the ends contact. Since the display device 10 includes a greater number of the light emitting elements ED in each subpixel SPXn and forms a series connection of the light emitting elements ED, the amount of light emitted per unit area can be increased.

The display device 10 may further include insulating layers PAS1 to PAS3 disposed between the electrodes RME1 and RME2, the light emitting elements ED, and the connection electrodes CNE1 to CNE3. The electrodes RME1 and RME2, the light emitting elements ED, and the connection electrodes CNE1 to CNE3 may overlap each other but may partially contact each other due to the insulating layers PAS1 to PAS3 disposed between them.

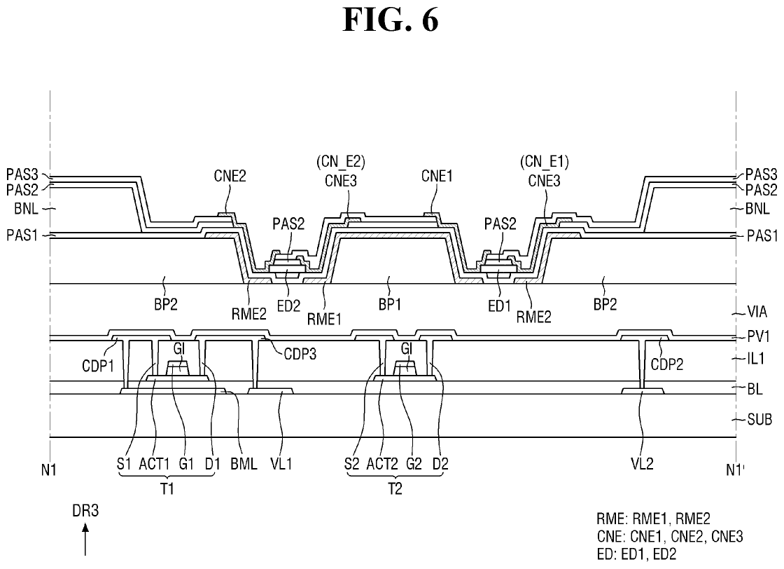

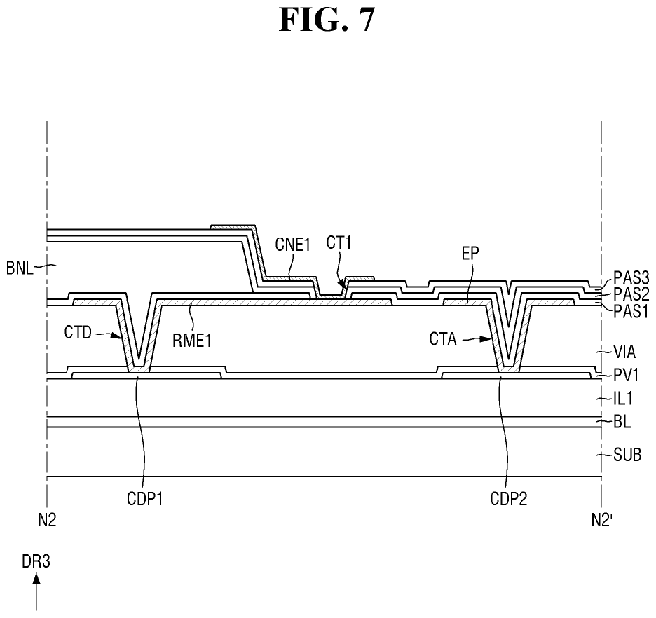

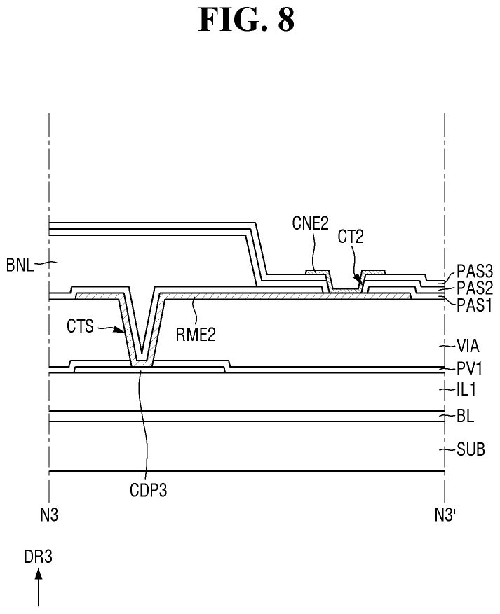

FIG. 6 is a schematic cross-sectional view taken along line N1-N1′ of FIG. 5. FIG. 7 is a schematic cross-sectional view taken along line N2-N2′ of FIG. 5. FIG. 8 is a schematic cross-sectional view taken along line N3-N3′ of FIG. 5.

FIG. 6 illustrates a cross section across ends of light emitting elements ED (ED1 and ED2) disposed on different electrodes RME (RME1 and RME2). FIGS. 7 and 8 illustrate cross sections across electrode contact holes CTD, CTS and CTA and the contact holes CT1 and CT2.

Referring to FIGS. 5 to 8, the display device 10 may include a first substrate SUB and a semiconductor layer, conductive layers and insulating layers disposed on the first substrate SUB. The display device 10 may include the electrodes RME, the light emitting elements ED, and the connection electrodes CNE.

The first substrate SUB may be an insulating substrate. The first substrate SUB may be made of an insulating material such as glass, quartz, or polymer resin. The first substrate SUB may be a rigid substrate, but may also be a flexible substrate that can be bent, folded, rolled, etc. The first substrate SUB may include the display area DPA and the non-display area NDA surrounding the display area DPA, and the display area DPA may include the emission area EMA and the sub-areas SA1 and SA2 which are part of the non-emission area.

A first conductive layer may include a bottom metal layer BML, a first voltage wiring VL1, and a second voltage wiring VL2. The bottom metal layer BML is overlapped by a first active layer ACT1 of a first transistor T1. The bottom metal layer BML may prevent light from entering the first active layer ACT1 of the first transistor T1 or may be electrically connected to the first active layer ACT1 to stabilize electrical characteristics of the first transistor T1. However, the bottom metal layer BML may also be omitted.

A high potential voltage (or a first power supply voltage) supplied to the first electrode RME1 may be applied to the first voltage wiring VL1, and a low potential voltage (or a second power supply voltage) supplied to each second electrode RME2 may be applied to the second voltage wiring VL2. The first voltage wiring VL1 may be electrically connected to the first transistor T1 through a conductive pattern (e.g., a third conductive pattern CDP3) of a second conductive layer. The second voltage wiring VL2 may be electrically connected to each second electrode RME2 through a conductive pattern (e.g., a second conductive pattern CDP2) of a third conductive layer.

Although FIG. 6 illustrates that the first voltage wiring VL1 and the second voltage wiring VL2 are disposed in the first conductive layer, the disclosure is not limited thereto. In some embodiments, the first voltage wiring VL1 and the second voltage wiring VL2 may be disposed in the third conductive layer and may be directly electrically connected to the first transistor T1 and each second electrode RME2, respectively.

A buffer layer BL may be disposed on the first conductive layer and the first substrate SUB. The buffer layer BL may be formed on the first substrate SUB to protect transistors of each pixel PX from moisture introduced through the first substrate SUB which is vulnerable to moisture penetration and may perform a surface planarization function.

The semiconductor layer is disposed on the buffer layer BL. The semiconductor layer may include the first active layerACT1 of the first transistor T1 and a second active layer ACT2 of a second transistor T2. The first active layer ACT1 and the second active layer ACT2 may respectively be partially overlapped by a first gate electrode G1 and a second gate electrode G2 of the second conductive layer which will be described below.

The semiconductor layer may include polycrystalline silicon, monocrystalline silicon, an oxide semiconductor, or the like. In an embodiment, the semiconductor layer may include polycrystalline silicon or an oxide semiconductor. The oxide semiconductor may include indium (In). For example, the oxide semiconductor may be at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), and indium gallium zinc tin oxide (IGZTO).

Although FIG. 6 illustrates that a first transistor T1 and a second transistor T2 are disposed in each subpixel SPXn of the display device 10, the disclosure is not limited thereto, and the display device 10 may include a greater number of transistors.

A first gate insulating layer GI is disposed on the semiconductor layer. The first gate insulating layer GI may serve as a gate insulating film of each of the transistors T1 and T2. FIG. 6 illustrates that the first gate insulating layer GI is patterned together with the gate electrodes G1 and G2 of the second conductive layer and thus partially disposed between the second conductive layer and the first and second active layers ACT1 and ACT2 of the semiconductor layer. However, the disclosure is not limited thereto. In some embodiments, the first gate insulating layer GI may cover the semiconductor layer and may be disposed on the entire surface of the buffer layer BL.

The second conductive layer is disposed on the first gate insulating layer GI. The second conductive layer may include the first gate electrode G1 of the first transistor T1 and the second gate electrode G2 of the second transistor T2. The first gate electrode G1 may overlap a channel region of the first active layer ACT1 in a third direction DR3 which is a thickness direction, and the second gate electrode G2 may overlap a channel region of the second active layer ACT2 in the third direction DR3 which is the thickness direction. Although not illustrated in the drawings, the second conductive layer may further include an electrode of a storage capacitor.

A first interlayer insulating layer IL1 is disposed on the second conductive layer. The first interlayer insulating layer IL1 may function as an insulating film between the second conductive layer and other layers disposed on the second conductive layer and may protect the second conductive layer.

The third conductive layer is disposed on the first interlayer insulating layer IL1. The third conductive layer may include conductive patterns CDP1 to CDP3 and a source electrode S1 or S2 and a drain electrode D1 or D2 of each of the transistors T1 and T2. Some of the conductive patterns CDP1 to CDP3 may electrically connect conductive layers or semiconductor layers on different layers and may serve as source/drain electrodes of the transistors T1 and T2.

A first conductive pattern CDP1 may contact the first active layer ACT1 of the first transistor T1 through a contact hole penetrating the first interlayer insulating layer IL1. The first conductive pattern CDP1 may contact the bottom metal layer BML through a contact hole penetrating the first interlayer insulating layer IL1 and the buffer layer BL. The first conductive pattern CDP1 may serve as a first source electrode S1 of the first transistor T1. The first conductive pattern CDP1 may be electrically connected to the first electrode RME1 or the first connection electrode CNE1. The first transistor T1 may transmit the first power supply voltage received from the first voltage wiring VL1 to the first electrode RME1 or the first connection electrode CNE1.

The second conductive pattern CDP2 may contact the second voltage wiring VL2 through a contact hole penetrating the first interlayer insulating layer IL1 and the buffer layer BL. The second voltage wiring VL2 may transfer the second power supply voltage to the second connection electrode CNE2 through the second conductive pattern CDP2.

The third conductive pattern CDP3 may contact the first voltage wiring VL1 through a contact hole penetrating the first interlayer insulating layer IL1 and the buffer layer BL. The third conductive pattern CDP3 may contact the first active layer ACT1 of the first transistor T1 through a contact hole penetrating the first interlayer insulating layer IL1. The third conductive pattern CDP3 may electrically connect the first voltage wiring VL1 to the first transistor T1 and may serve as a first drain electrode D1 of the first transistor T1.

Each of a second source electrode S2 and a second drain electrode D2 may contact the second active layer ACT2 of the second transistor T2 through a contact hole penetrating the first interlayer insulating layer IL1.

A first passivation layer PV1 is disposed on the third conductive layer. The first passivation layer PV1 may function as an insulating film between the third conductive layer and other layers and may protect the third conductive layer.

Each of the buffer layer BL, the first gate insulating layer GI, the first interlayer insulating layer IL1, and the first passivation layer PV1 described above may be composed of inorganic layers stacked each other alternately. For example, each of the buffer layer BL, the first gate insulating layer GI, the first interlayer insulating layer IL1, and the first passivation layer PV1 may be a double layer in which inorganic layers including at least any one of silicon oxide (SiOₓ), silicon nitride (SiNₓ) and silicon oxynitride (SiOₓN_{y}) are stacked each other or may be a multilayer in which the above inorganic layers are alternately stacked each other. However, the disclosure is not limited thereto, and each of the buffer layer BL, the first gate insulating layer GI, the first interlayer insulating layer IL1, and the first passivation layer PV1 may also be composed of an inorganic layer including any one of the above insulating materials. In some embodiments, the first interlayer insulating layer IL1 may be made of an organic insulating material such as polyimide (PI).

A via layer VIA is disposed on the third conductive layer in the display area DPA. The via layer VIA may include an organic insulating material such as polyimide (PI) to compensate for a step difference due to the conductive layers under the via layer VIA and may form a flat upper surface. However, in some embodiments, the via layer VIA may be omitted.

The display device 10 may include, as a display element layer disposed on the via layer VIA, the barrier walls BP1 and BP2, the electrodes RME1 and RME2, the bank layer BNL, the light emitting elements ED1 and ED2, and the connection electrodes CNE1 to CNE3. The display device 10 may include the insulating layers PAS1 to PAS3.

The barrier walls BP1 and BP2 may be disposed on the via layer VIA. For example, the barrier walls BP1 and BP2 may be disposed directly on the via layer VIA, and at least a portion of each of the barrier walls BP1 and BP2 may protrude from an upper surface of the via layer VIA. As described above, the first barrier wall BP1 and the second barrier walls BP2 may be spaced apart from each other, and the first barrier wall BP1 may be disposed between the second barrier walls BP2. Each of the barrier walls BP1 and BP2 may have inclined side surfaces or curved side surfaces with a curvature (e.g., a predetermined or selectable curvature), and light emitted from the light emitting elements ED 1 and ED2 may be reflected upward above the via layer VIA by the electrodes RME1 and RME2 disposed on the barrier walls BP1 and BP2. Unlike in the drawings, each of the barrier walls BP1 and BP2 may also have a shape having an outer surface curved with a curvature (e.g., a predetermined or selectable curvature) in a cross-sectional view, for example, may have a semicircular or semielliptical shape. The barrier walls BP1 and BP2 may include, but are not limited to, an organic insulating material such as polyimide (PI).

The electrodes RME1 and RME2 may be disposed on the barrier walls BP1 and BP2 and the via layer VIA. For example, a portion of each of the electrodes RME1 and RME2 may be disposed on at least the inclined side surfaces of a barrier wall BP1 or BP2. The first electrode RME1 may cover the first barrier wall BP1, and the electrode branch portions RM_B1 and RM_B2 of each second electrode RME2 may cover the side surfaces of a second barrier wall BP2. A width of the first electrode RME1 may be greater than that of the first barrier wall BP1, and widths of the electrode branch portions RM_B1 and RM_B2 of each second electrode RME2 may be smaller than that of the second barrier wall BP2. The distance between the electrodes RME spaced apart from each other in the second direction DR2 may be smaller than the distance between the barrier walls BP1 and BP2. At least a portion of each of the electrodes RME may be disposed directly on the via layer VIA so that they lie in a same plane.

The light emitting elements ED disposed between the barrier walls BP1 and BP2 may emit light toward ends thereof, and the emitted light may travel toward the electrodes RME disposed on the barrier walls BP1 and BP2. Each electrode RME may have a structure in which a portion thereof disposed on a barrier wall BP1 or BP2 can reflect light emitted from the light emitting elements ED. Each electrode RME may cover at least one side surface of the barrier wall BP1 or BP2 to reflect light emitted from the light emitting elements ED.

Each of the first and second electrodes RME1 and RME2 may directly contact the third conductive layer through an electrode contact hole CTD or CTS disposed in a portion thereof overlapping the bank layer BNL. For example, a first electrode contact hole CTD may be formed in a portion in which the first electrode RME1 and the bank layer BNL overlap each other, and a second electrode contact hole CTS may be formed in a portion in which each second electrode RME2 and the bank layer BNL overlap each other. The first electrode RME1 may contact the first conductive pattern CDP1 through the first electrode contact hole CTD penetrating the via layer VIA and the first passivation layer PV1 and may be electrically connected to the first transistor T1. Each second electrode RME2 may contact the second conductive pattern CDP2 through the second electrode contact hole CTS penetrating the via layer VIA and the first passivation layer PV1 and may be electrically connected to the second voltage wiring VL2.

The wiring connection electrode EP may be disposed in the first sub-area SA1 and may directly contact the third conductive layer through a third electrode contact hole CTA. For example, the wiring connection electrode EP may contact the third conductive pattern CDP3 through the third electrode contact hole CTA penetrating the via layer VIA and the first passivation layer PV1. The wiring connection electrode EP may be electrically connected to the first voltage wiring VL1 through the third conductive pattern CDP3.

In a manufacturing process of the display device 10, the first electrode RME1 may be formed to be connected to the wiring connection electrode EP, and an electrical signal transmitted to place the light emitting elements ED may be transmitted from the first voltage wiring VL1 to the first electrode RME1 through the wiring connection electrode EP. In the process of placing the light emitting elements ED, signals may be transmitted to the first voltage wiring VL1 and the second voltage wiring VL2 and may be transferred to the first and second electrodes RME1 and RME2, respectively.

In an embodiment, the relative positions of the first electrode contact hole CTD and the second electrode contact hole CTS may be different from that of the third electrode contact hole CTA. The first electrode contact hole CTD may be disposed in each of the first sub-area SA1 and the second sub-area SA2, and the second electrode contact hole CTS may be formed to overlap the bank layer BNL located on a side of each sub-area SA1 or SA2 in the second direction DR2. On the other hand, the third electrode contact hole CTA may be disposed only in the first sub-area SA1. For example, since the second electrode contact hole CTS and the third electrode contact hole CTA expose upper surfaces of different voltage wirings VL1 and VL2, respectively, the position of each of the second electrode contact hole CTS and the third electrode contact hole CTA may be determined accordingly. In the case of the separation portions ROP1 and ROP2 in which the electrodes RME are separated, the first separation portions ROP1 may be disposed in the first sub-area SA1 and may be formed above and below the wiring connection electrode EP, respectively. On the other hand, the second separation portion ROP2 may be disposed in the second sub-area SA2 and may be disposed between the first electrodes RME1. Two first separation portions ROP1 may be formed in the first sub-area SA1, and a second separation portion ROP2 may be formed in the second sub-area SA2.

The electrodes RME may include a conductive material having high reflectivity. For example, each of the electrodes RME may include a metal such as silver (Ag), copper (Cu) or aluminum (Al), may be an alloy including aluminum (Al), nickel (Ni) or lanthanum (La), or may have a structure in which a metal layer such as titanium (Ti), molybdenum (Mo) or niobium (Nb) and the above alloy are stacked each other. In some embodiments, each of the electrodes RME may be a double layer or a multilayer in which an alloy including aluminum (Al) and at least one metal layer made of titanium (Ti), molybdenum (Mo) or niobium (Nb) are stacked each other.

However, the disclosure is not limited thereto, and each electrode RME may further include a transparent conductive material. For example, each electrode RME may include a material such as ITO, IZO or ITZO. In some embodiments, each electrode RME may have a structure in which a transparent conductive material and a metal layer having high reflectivity are each stacked in one or more layers or may be formed as a single layer including the transparent conductive material and the metal layer. For example, each electrode RME may have a stacked structure of ITO/Ag/ITO, ITO/Ag/IZO, or ITO/Ag/ITZO/IZO. The electrodes RME may be electrically connected to the light emitting elements ED and may reflect some of the light emitted from the light emitting elements ED in an upward direction of the first substrate SUB.

A first insulating layer PAS1 may be disposed in the entire display area DPA and may be disposed on the via layer VIA and the electrodes RME. The first insulating layer PAS1 may protect the electrodes RME while insulating them from each other. Since the first insulating layer PAS1 covers the electrodes RME before the bank layer BNL is formed, it may prevent the electrodes RME from being damaged in the process of forming the bank layer BNL. The first insulating layer PAS1 may prevent the light emitting elements ED on the first insulating layer PAS1 from being damaged by directly contacting other members.

In an embodiment, the first insulating layer PAS1 may be stepped such that a portion of an upper surface of the first insulating layer PAS1 is recessed between the electrodes RME spaced apart from each other in the second direction DR2. The light emitting elements ED may be disposed on the stepped upper surface of the first insulating layer PAS1, and a space may be formed between the light emitting elements ED and the first insulating layer PAS1.

According to an embodiment, the first insulating layer PAS1 may include separation openings formed to correspond to the separation portions ROP1 and ROP2 and the contact holes CT1 and CT2. The first insulating layer PAS1 may be disposed on the entire surface of the via layer VIA but may partially expose layers under the first insulating layer PAS1 in portions in which the separation openings and the contact holes CT1 and CT2 are formed.

The separation openings are openings formed in the first insulating layer PAS1 to correspond to the separation portions ROP1 and ROP2 of the sub-areas SA1 and SA2 and may expose the via layer VIA disposed under the separation openings. In the separation openings of the first insulating layer PAS1, a process of separating the first electrodes RME1 connected to each other may be performed. The first electrode RME1 extending in the first direction DR1 in each subpixel SPXn may be formed to be connected to the first electrodes RME1 of other subpixels SPXn adjacent to each other in the first direction DR1 or the wiring connection electrode EP and may be separated from them as portions exposed by the separation openings of the first insulating layer PAS1 are etched. The separation openings of the first insulating layer PAS1 may be disposed to correspond to the separation portions ROP1 and ROP2 located between the first electrodes RME1 or between the first electrode RME1 and the wiring connection electrode EP.

The contact holes CT1 and CT2 of the first insulating layer PAS1 may respectively overlap different electrodes RME in the sub-areas SA1 and SA2. For example, the contact holes CT1 and CT2 may include first contact holes CT1 overlapping the first electrodes RME1 and second contact holes CT2 overlapping the second electrodes RME2. The first and second contact holes CT1 and CT2 may be disposed in each of the sub-areas SA1 and SA2. The first contact hole CT1 disposed in the first sub-area SA1 may be spaced apart from the first separation portion ROP1 disposed below the wiring connection electrode EP and may be disposed on the first electrode RME1. The first contact hole CT1 disposed in the second sub area SA2 may be spaced apart from the second separation portion ROP2 and may be disposed on the first electrode RME1 of another subpixel SPXn. The second contact hole CT2 may be disposed on a portion protruding from the electrode stem portion RM_S of each second electrode RME2 to each of the sub-areas SA1 and SA2.

The first contact holes CT1 and the second contact holes CT2 may penetrate the first insulating layer PAS1 to partially expose upper surfaces of the first electrodes RME1 or the second electrodes RME2 under the first and second contact holes CT1 and CT2. The first contact holes CT1 and the second contact holes CT2 may further penetrate some of other insulating layers disposed on the first insulating layer PAS1. The electrodes RME exposed by the contact holes CT1 and CT2 may contact the connection electrodes CNE.

The bank layer BNL may be disposed on the first insulating layer PAS1. The bank layer BNL may include portions extending in the first direction DR1 and the second direction DR2 and may surround each subpixel SPXn. The bank layer BNL may surround the emission area EMA and the sub-areas SA1 and SA2 of each subpixel SPXn to separate them and may surround the outermost periphery of the display area DPA to separate the display area DPA and the non-display area NDA. Of the bank layer BNL, portions extending in the second direction DR2 may separate the emission areas EMA from the sub-areas SA1 and SA2, and portions extending in the first direction DR1 may separate adjacent subpixels SPXn. The portions of the bank layer BNL which extend in the first direction DR1 may be disposed on the second barrier walls BP2.

Similar to the barrier walls BP1 and BP2, the bank layer BNL may have a height (e.g., a predetermined or selectable height). In some embodiments, an upper surface of the bank layer BNL may be at a greater height than those of the barrier walls BP1 and BP2, and a thickness of the bank layer BNL may be equal to or greater than those of the barrier walls BP1 and BP2. The bank layer BNL may prevent ink from overflowing to adjacent subpixels SPXn in an inkjet printing process during the manufacturing process of the display device 10. Similar to the barrier walls BP1 and BP2, the bank layer BNL may include an organic insulating material such as polyimide. However, the disclosure is not limited thereto, and the bank layer BNL may also include a material different from that of the barrier walls BP1 and BP2.

The light emitting elements ED may be disposed in the emission area EMA. The light emitting elements ED may be disposed on the first insulating layer PAS1 between the barrier walls BP1 and BP2. A direction in which the light emitting elements ED extend may be substantially parallel to an upper surface of the first substrate SUB. As will be described below, each light emitting element ED may include semiconductor layers disposed in the extending direction, and the semiconductor layers may be sequentially disposed in a direction parallel to the upper surface of the first substrate SUB. However, the disclosure is not limited thereto. In case that each of the light emitting elements ED has a different structure, the semiconductor layers may be disposed in a direction perpendicular to the first substrate SUB.

The light emitting elements ED disposed in the subpixels SPXn may emit light of different wavelength bands depending on the materials that form the semiconductor layers described above. However, the disclosure is not limited thereto, and the light emitting elements ED disposed in the subpixels SPXn may also emit light of a same color by including the semiconductor layers made of a same material.

The light emitting elements ED may be disposed on different electrodes RME between different barrier walls BP1 and BP2. The first light emitting elements ED1 may be disposed between the first barrier wall BP1 and a second barrier wall BP2 and may have ends disposed on the first electrode RME1 and the second electrode branch portion RM_B2 of a second electrode RME2. The second light emitting elements ED2 may be disposed between a second barrier wall BP2 and the first barrier wall BP1 and may have ends disposed on the first electrode RME1 and the first electrode branch portion RM_B1 of a second electrode RME2. The first light emitting elements ED1 may be disposed on the right side of the first barrier wall BP1 in the emission area EMA, and the second light emitting elements ED2 may be disposed on the left side of the first barrier wall BP1.

The light emitting elements ED may be electrically connected to the electrodes RME and the conductive layers under the via layer VIA by contacting the connection electrodes CNE and may emit light of a specific wavelength band in response to an electrical signal.

A second insulating layer PAS2 may be disposed on the light emitting elements ED, the first insulating layer PAS1, and the bank layer BNL. The second insulating layer PAS2 includes a pattern portion extending in the first direction DR1 between the barrier walls BP1 and BP2 and disposed on the light emitting elements ED. The pattern portion may partially cover outer surfaces of the light emitting elements ED and may not cover sides or ends of the light emitting elements ED. The pattern portion may form a linear or island-shaped pattern in each subpixel SPXn in a plan view. The pattern portion of the second insulating layer PAS2 may protect the light emitting elements ED while anchoring the light emitting elements ED in the manufacturing process of the display device 10. The second insulating layer PAS2 may be formed to fill a space between the light emitting elements ED and first insulating layer PAS1 under the light emitting elements ED. A portion of the second insulating layer PAS2 may be disposed on the bank layer BNL and in the sub-areas SA1 and SA2.

According to an embodiment, the second insulating layer PAS2 may include separation openings formed to correspond to the separation portions ROP1 and ROP2 and the contact holes CT1 and CT2. The second insulating layer PAS2 may be disposed on the entire surface of the first insulating layer PAS1 but may partially expose layers under the second insulating layer PAS2 in portions in which the separation openings and the contact holes CT1 and CT2 are formed. The separation openings and the contact holes CT1 and CT2 are the same as those described above in relation to the first insulating layer PAS1.

The connection electrodes CNE may be disposed on the electrodes RME and the barrier walls BP1 and BP2. The connection electrodes CNE may be divided into a connection electrode of a first connection electrode layer disposed between the second insulating layer PAS2 and a third insulating layer PAS3 and a connection electrode of a second connection electrode layer disposed on the third insulating layer PAS3. The third connection electrode CNE3 may be a connection electrode of the first connection electrode layer, and the first connection electrode CNE1 and the second connection electrode CNE2 may be connection electrodes of the second connection electrode layer.

The first connection electrode CNE1 may be disposed on the first electrode RME1 and the first barrier wall BP1. The second connection electrode CNE2 may be disposed on a second electrode RME2 and a second barrier wall BP2. The third connection electrode CNE3 may be disposed on the first electrode RME1, a second electrode RME2, a second barrier wall BP2, and the first barrier wall BP1. The planar placement of each connection electrode CNE is the same as that described above with reference to FIG. 5.

Each of the first connection electrode CNE1, the second connection electrode CNE2, and the third connection electrode CNE3 may be disposed on the second insulating layer PAS2 and may contact the light emitting elements ED. The first connection electrode CNE1 may contact first ends of the first light emitting elements ED1. The second connection electrode CNE2 may contact second ends of the second light emitting elements ED2. In the third connection electrode CNE3, the first extension portion CN_E1 may contact second ends of the first light emitting elements ED1, and the second extension portion CN_E2 may contact first ends of the second light emitting elements ED2.

The first connection electrode CNE1 and the second connection electrode CNE2 may be disposed over the emission area EMA and the sub-area SA1 or SA2 and may directly contact the electrodes RME1 and RME2 through the contact holes CT1 and CT2 formed in the sub-area SA1 or SA2. The first connection electrode CNE1 may contact the first electrode RME1 through a first contact hole CT1 penetrating the first insulating layer PAS1, the second insulating layer PAS2, and the third insulating layer PAS3 in the sub-area SA1 or SA2. The second connection electrode CNE2 may contact a second electrode RME2 through a second contact hole CT2 penetrating the first insulating layer PAS1, the second insulating layer PAS2, and the third insulating layer PAS3 in the sub-area SA1 or SA2. On the other hand, the third connection electrode CNE3 may not contact the electrodes RME.

The first connection electrode CNE1 may be electrically connected to the first transistor T1 through the first electrode RME1 to receive the first power supply voltage, and the second connection electrode CNE2 may be electrically connected to the second voltage wiring VL2 through a second electrode RME2 to receive the second power supply voltage. The light emitting elements ED may emit light by the power supply voltages received through the first connection electrode CNE1 and the second connection electrode CNE2.

The first connection electrode CNE1 and the second connection electrode CNE2 may be first type connection electrodes connected to the electrodes RME1 and RME2 directly connected to the third conductive layer, and the third connection electrode CNE3 may be a second type connection electrode not connected to the electrodes RME. The third connection electrode CNE3 may not be connected to the electrodes RME but may contact the light emitting elements ED and may form an electrical connection circuit of the light emitting elements ED together with other connection electrodes CNE.

However, the disclosure is not limited thereto. In some embodiments, in the display device 10, some of the connection electrodes CNE may be directly connected to the third conductive layer. For example, the first connection electrode CNE1 and the second connection electrode CNE2 which are first type connection electrodes may be directly connected to the third conductive layer and may not be electrically connected to the electrodes RME. A second type connection electrode may also not be electrically connected to the electrodes RME and may be connected only to the light emitting elements ED.

The connection electrodes CNE may include a conductive material such as ITO, IZO, ITZO, or aluminum (Al). For example, the connection electrodes CNE may include a transparent conductive material, and light emitted from the light emitting elements ED may be output through the connection electrodes CNE.

The third insulating layer PAS3 is disposed on the connection electrodes of the second connection electrode layer and the second insulating layer PAS2. The third insulating layer PAS3 may be disposed on the entire surface of the second insulating layer PAS2 to cover the third connection electrode CNE3, and the first connection electrode CNE1 and the second connection electrode CNE2 may be disposed on the third insulating layer PAS3. The third insulating layer PAS3 may be disposed on the entire surface of the via layer VIA except for an area where the third connection electrode CNE3 is disposed. The third insulating layer PAS3 may insulate the connection electrodes of the first connection electrode layer from the connection electrodes of the second connection electrode layer so that they do not directly contact each other.

According to an embodiment, the third insulating layer PAS3 may include contact holes CT1 and CT2. The third insulating layer PAS3 may be disposed on the entire surface of the second insulating layer PAS2 but may partially expose layers under the third insulating layer PAS3 in portions in which the contact holes CT1 and CT2 are formed. The first and second contact holes CT1 and CT2 may penetrate the third insulating layer PAS3 in addition to the first insulating layer PAS1 and the second insulating layer PAS2. Each of the contact holes CT1 and CT2 may expose a portion of the upper surface of an electrode RME under the contact hole CT1 or CT2.

Each of the first insulating layer PAS1, the second insulating layer PAS2 and the third insulating layer PAS3 described above may include an inorganic insulating material or an organic insulating material. For example, each of the first insulating layer PAS1, the second insulating layer PAS2 and the third insulating layer PAS3 may include an inorganic insulating material. As another example, the first insulating layer PAS1 and the third insulating layer PAS3 may include an inorganic insulating material, and the second insulating layer PAS2 may include an organic insulating material. Each or at least one of the first insulating layer PAS1, the second insulating layer PAS2 and the third insulating layer PAS3 may be formed in a structure in which insulating layers are alternately or repeatedly stacked each other. In an embodiment, each of the first insulating layer PAS1, the second insulating layer PAS2 and the third insulating layer PAS3 may be at least one of silicon oxide (SiOₓ), silicon nitride (SiNₓ), and silicon oxynitride (SiOₓN_{y}). The first insulating layer PAS1, the second insulating layer PAS2, and the third insulating layer PAS3 may be made of a same material, or some thereof may be made of a same material while others are made of different materials, or all of them may be made of different materials.

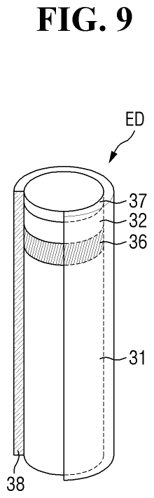

FIG. 9 is a schematic view of a light emitting element ED according to an embodiment.

Referring to FIG. 9, the light emitting element ED may be a light emitting diode. Specifically, the light emitting element ED may be an inorganic light emitting diode having a size of nanometers to micrometers and made of an inorganic material. In case that an electric field is formed in a specific direction between two electrodes facing each other, the light emitting element ED may be aligned between the two electrodes in which polarities are formed.

The light emitting element ED according to the embodiment may extend in a direction. The light emitting element ED may be shaped like a cylinder, a rod, a wire, a tube, or the like. However, the shape of the light emitting element ED is not limited thereto, and the light emitting element ED may also have various shapes including polygonal prisms, such as a cube, a rectangular parallelepiped or a hexagonal prism, and a shape extending in a direction and having a partially inclined outer surface.

The light emitting element ED may include a semiconductor layer doped with a dopant of any conductivity type (e.g., a p-type or an n-type). The semiconductor layer may receive an electrical signal from an external power source and emit light of a specific wavelength band. The light emitting element ED may include a first semiconductor layer 31, a second semiconductor layer 32, a light emitting layer 36, an electrode layer 37, and an insulating film 38.

The first semiconductor layer 31 may be an n-type semiconductor. The first semiconductor layer 31 may include a semiconductor material having a chemical formula of AlₓGa_{y}In_{1-x-y}N (0≤x≤1, 0≤y≤1, 0≤x+y≤1). For example, the first semiconductor layer 31 may be at least one of AlGaInN, GaN, AlGaN, InGaN, MN, and InN doped with an n-type dopant. The n-type dopant used to dope the first semiconductor layer 31 may be Si, Ge, Sn, Se, or the like.

The second semiconductor layer 32 is disposed on the first semiconductor layer 31 with the light emitting layer 36 interposed between them. The second semiconductor layer 32 may be a p-type semiconductor. The second semiconductor layer 32 may include a semiconductor material having a chemical formula of AlₓGa_{y}In_{1-x-y}N (0≤x≤1, 0≤y≤1, For example, the second semiconductor layer 32 may be at least one of AlGaInN, GaN, AlGaN, InGaN, AlN, and InN doped with a p-type dopant. The p-type dopant used to dope the second semiconductor layer 32 may be Mg, Zn, Ca, Ba, or the like.

Although FIG. 9 illustrates that each of the first semiconductor layer 31 and the second semiconductor layer 32 is composed of a layer, the disclosure is not limited thereto. Each of the first semiconductor layer 31 and the second semiconductor layer 32 may also include more layers, and for example, may further include a clad layer or a tensile strain barrier reducing (TSBR) layer depending on the material of the light emitting layer 36. For example, the light emitting element ED may further include another semiconductor layer disposed between the first semiconductor layer 31 and the light emitting layer 36 or between the second semiconductor layer 32 and the light emitting layer 36. The semiconductor layer disposed between the first semiconductor layer 31 and the light emitting layer 36 may be any one or more of AlGaInN, GaN, AlGaN, InGaN, AlN, InN and SLs doped with an n-type dopant. The semiconductor layer disposed between the second semiconductor layer 32 and the light emitting layer 36 may be at least one of AIGaInN, GaN, AlGaN, InGaN, AlN, and InN doped with a p-type dopant.

The light emitting layer 36 is disposed between the first semiconductor layer 31 and the second semiconductor layer 32. The light emitting layer 36 may include a material having a single or multiple quantum well structure. In case that the light emitting layer 36 includes a material having a multiple quantum well structure, it may have a structure in which quantum layers and well layers are alternately stacked each other. The light emitting layer 36 may emit light through combination of electron-hole pairs according to electrical signals received through the first semiconductor layer 31 and the second semiconductor layer 32. The light emitting layer 36 may include a material such as AlGaN, AlGaInN, or InGaN. In particular, in case that the light emitting layer 36 has a multiple quantum well structure in which a quantum layer and a well layer are alternately stacked each other, the quantum layer may include a material such as AlGaN or AlGaInN, and the well layer may include a material such as GaN or AlInN.

The light emitting layer 36 may also have a structure in which a semiconductor material having a large band gap energy and a semiconductor material having a small band gap energy are alternately stacked each other or may include different group III to V semiconductor materials depending on the wavelength band of light that it emits. Light emitted from the light emitting layer 36 is not limited to light in a blue wavelength band. In some embodiments, the light emitting layer 36 may emit light in a red or green wavelength band.

The electrode layer 37 may be an ohmic connection electrode. However, the disclosure is not limited thereto, and the electrode layer 37 may also be a Schottky connection electrode. The light emitting element ED may include at least one electrode layer 37. The light emitting element ED may include one or more electrode layers 37. However, the disclosure is not limited thereto, and the electrode layer 37 may also be omitted.

In case that the light emitting element ED is electrically connected to electrodes or connection electrodes in the display device 10, the electrode layer 37 may reduce the resistance between the light emitting element ED and the electrodes or the connection electrodes. The electrode layer 37 may include a conductive metal. For example, the electrode layer 37 may include at least one of aluminum (Al), titanium (Ti), indium (In), gold (Au), silver (Ag), indium tin oxide (ITO), indium zinc oxide (IZO), and indium tin zinc oxide (ITZO).

The insulating film 38 surrounds outer surfaces of the semiconductor layers and the electrode layer described above. For example, the insulating film 38 may surround an outer surface of at least the light emitting layer 36 but may expose ends of the light emitting element ED in a longitudinal direction. An upper surface of the insulating film 38 may be rounded in a cross-sectional view in an area adjacent to at least one end of the light emitting element ED.

The insulating film 38 may include an insulating material, for example, at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). Although FIG. 9 illustrates that the insulating film 38 is formed as a single layer, the disclosure is not limited thereto. In some embodiments, the insulating film 38 may be formed in a multilayer structure in which layers are stacked each other.

The insulating film 38 may protect the semiconductor layers and the electrode layer of the light emitting element ED. The insulating film 38 may prevent an electrical short circuit that may occur in the light emitting layer 36 in case that the light emitting layer 36 directly contacts an electrode that transmits an electrical signal to the light emitting element ED. The insulating film 38 may prevent a reduction in luminous efficiency of the light emitting element ED.

An outer surface of the insulating film 38 may be treated. The light emitting element ED may be sprayed onto electrodes in a state where it is dispersed in an ink and may be aligned. The surface of the insulating film 38 may be hydrophobically or hydrophilically treated so that the light emitting element ED is kept dispersed in the ink without being agglomerated with other adjacent light emitting elements ED.

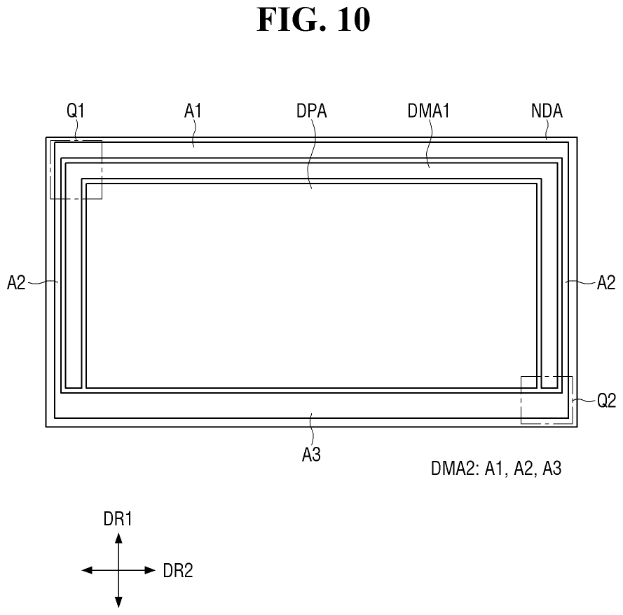

FIG. 10 illustrates the schematic arrangement of the display area DPA and dummy pixel areas DMA1 and DMA2 of the display device 10 according to the embodiment.

Referring to FIG. 10, the display device 10 according to the embodiment may include the display area DPA and the non-display area NDA, and the non-display area NDA may include the dummy pixel areas DMA1 and DMA2 disposed around the display area DPA. The pixels PX described above with reference to FIGS. 5 to 8 may be disposed in the display area DPA. The pixels PX disposed in the display area DPA may include the light emitting elements ED and the electrodes RME1 and RME2 to emit light.

The dummy pixel areas DMA1 and DMA2 may include a first dummy pixel area DMA1 disposed around the display area DPA and a second dummy pixel area DMA2 having a portion disposed outside the first dummy pixel area DMA1. The first dummy pixel area DMA1 may be disposed on an upper side of the display area DPA which is a side in the first direction DR1 and on left and right sides of the display area DPA which are sides in the second direction DR2. The first dummy pixel area DMA1 may surround the upper, left, and right sides of the display area DPA. The second dummy pixel area DMA2 may surround the first dummy pixel area DMA1 and the display area DPA. The second dummy pixel area DMA2 may include a first area A1 disposed on an upper side of the first dummy pixel area DMA1, a second area A2 disposed on left and right sides of the first dummy pixel area DMA1, and a third area A3 disposed on a lower side of the display area DPA. Since the first dummy pixel area DMA1 is not disposed on the lower side of the display area DPA, the second dummy pixel area DMA2 may contact the display area DPA on the lower side of the display area DPA.

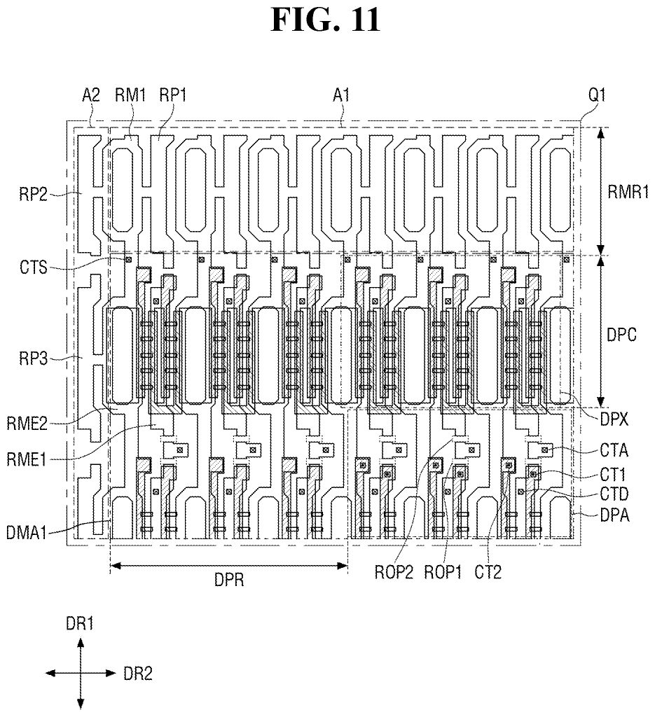

According to an embodiment, in the first dummy pixel area DMA1, dummy pixels DPX (see FIG. 11) which have the same structure as the pixels PX of the display area DPA but whose light emitting elements ED do not emit light may be disposed. The second dummy pixel area DMA2 may include dummy electrode lines RM1 (see FIG. 11) and dummy electrode patterns RP1 to RP3 (see FIG. 11) having a similar shape to the electrodes RME1 and RME2 of the display area DPA. The electrodes RME1 and RME2, the dummy electrode lines RM1, and the dummy electrode patterns RP1 to RP3 disposed in the dummy pixels DPX, and the electrodes RME1 and RME2 disposed in the display area DPA may be formed in a same process. The display device 10 may include the dummy pixels DPX, the dummy electrode lines RM1 and the dummy electrode patterns RP1 to RP3 disposed around the display area DPA so that a distance between the electrodes RME1 and RME2 disposed in the display area DPA is constant regardless of position in the display area DPA.

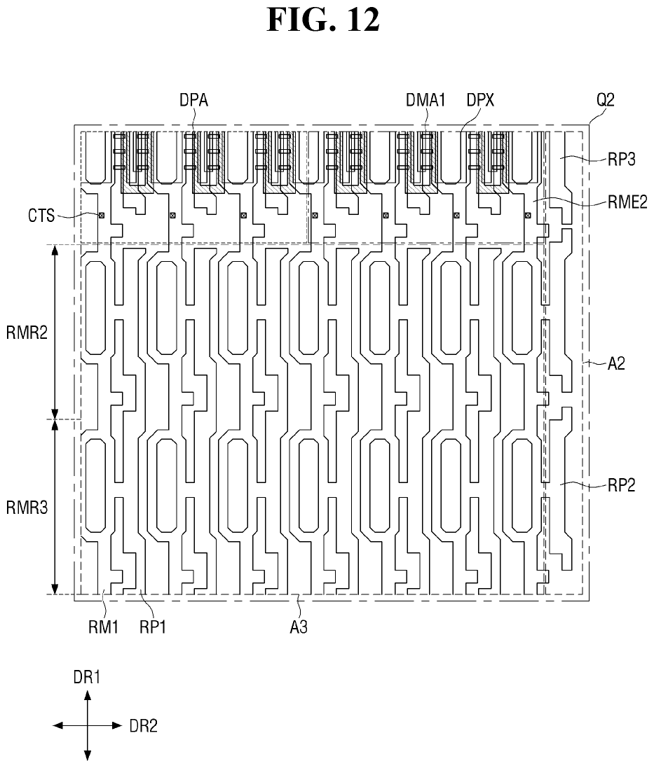

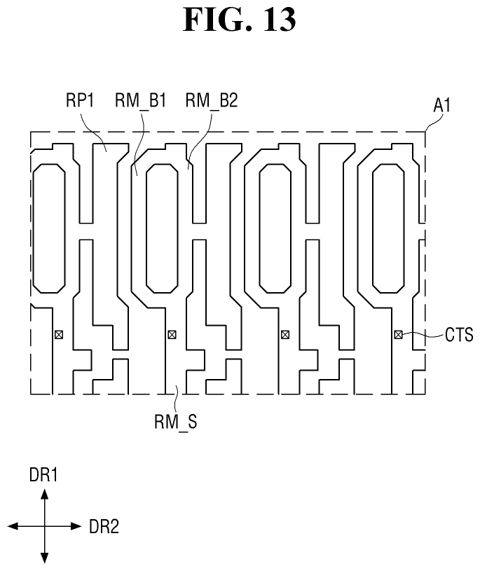

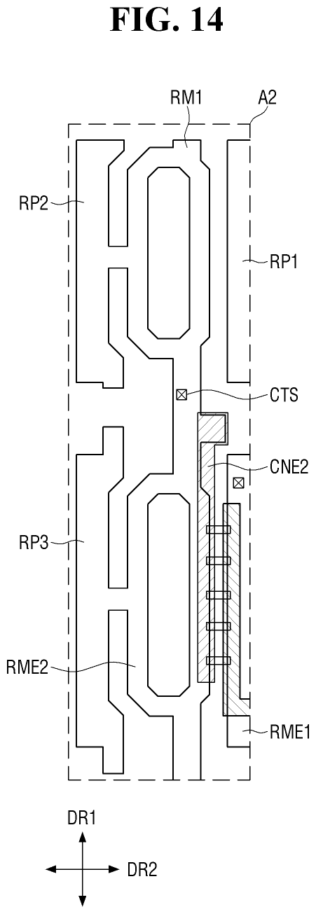

FIG. 11 is a schematic plan view of portion Q1 of FIG. 10. FIG. 12 is a schematic plan view of portion Q2 of FIG. 10. FIG. 13 is a plan view illustrating the arrangement of dummy electrodes in the first area A1 of the second dummy pixel area DMA2 of the display device 10 according to the embodiment. FIG. 14 is a plan view illustrating the arrangement of dummy electrodes in the second area A2 of the second dummy pixel area DMA2 of the display device 10 according to the embodiment.

FIG. 11 illustrates a portion of the first dummy pixel area DMA1 and the second dummy pixel area DMA2 disposed on an upper left side of the display area DPA, and FIG. 12 illustrates a portion of the first dummy pixel area DMA1 and the second dummy pixel area DMA2 disposed on a lower right side of the display area DPA. FIG. 11 illustrates first dummy electrode lines RM1 and first dummy electrode patterns RP1 disposed in the first area A1 of the second dummy pixel area DMA2 and second and third dummy electrode patterns RP2 and RP3 disposed in the second area A2. FIG. 12 illustrates second and third dummy electrode patterns RP2 and RP3 disposed in the second area A2 of the second dummy pixel area DMA2 and first dummy electrode lines RM1 and first dummy electrode patterns RP1 disposed in the third area A3.

Referring to FIGS. 11 to 14, the display device 10 according to the embodiment may include dummy pixels DPX disposed in the first dummy pixel area DMA1 around the display area DPA. The dummy pixels DPX and the pixels PX disposed in the display area DPA may have substantially a same structure. Each of the dummy pixels DPX may include subpixels SPXn, and each of the subpixels SPXn may include first and second electrodes RME1 and RME2 and light emitting elements ED and connection electrodes CNE1 to CNE3 disposed on the first and second electrodes RME1 and RME2. Although not illustrated in the drawings, the bank layer BNL and the barrier walls BP1 and BP2 may also be disposed in the dummy pixels DPX, and the bank layer BNL may surround the emission areas EMA and the sub-areas SA1 and SA2 of the dummy pixels DPX. The detailed structure of the dummy pixels DPX not illustrated in the drawings is substantially the same as the structure of the pixels PX described above with reference to FIG. 5.

For example, the first electrodes RME1 of the dummy pixels DPX may be spaced apart from each other in the first direction DR1 from the first electrodes RME1 of the pixels PX of the display area DPA in the sub-areas SA1 and SA2. The second electrodes RME2 of the dummy pixels DPX may be connected to the second electrodes RME2 disposed in the pixels PX of the display area DPA. Pixels PX disposed in an uppermost portion of the display area DPA may be pixels PX having the first sub-area SA1 disposed above the emission area EMA, and dummy pixels DPX adjacent to the uppermost pixels PX may have the second sub-area SA2 disposed above the emission area EMA.

The light emitting elements ED may be disposed in the dummy pixels DPX but may not emit light, unlike in the pixels PX of the display area DPA. According to an embodiment, the first and second contact holes CT1 and CT2 may not be formed in the dummy pixels DPX. Therefore, the connection electrodes CNE1 to CNE3 may not contact the electrodes RME1 and RME2. First and second connection electrodes CNE1 and CNE2 disposed in the dummy pixels DPX may extend in the first direction DR1 and may be disposed in the emission areas EMA and the sub-areas SA1 and SA2 of the dummy pixels DPX. However, the contact holes CT1 and CT2 may not be formed in the sub-areas SA1 and SA2 of the dummy pixels DPX, and the first and second connection electrodes CNE1 and CNE2 may not contact the electrodes RME1 and RME2. The light emitting elements ED of the dummy pixels DPX may contact the connection electrodes CNE1 to CNE3 but may not be electrically connected to the electrodes RME1 and RME2 and may not emit light.

FIGS. 11 and 12 illustrate that a dummy pixel row DPC is disposed in the first dummy pixel area DMA1 located on the upper side of the display area DPA, and a dummy pixel column DPR is disposed in the first dummy pixel area DMA1 located on each of the left and right sides of the display area DPA. However, the disclosure is not limited thereto. One or more dummy pixel rows or dummy pixel columns may also be disposed in the first dummy pixel area DMA1 around the display area DPA.

The display device 10 according to the embodiment may include the dummy electrode lines RM1 and the dummy electrode patterns RP1 to RP3 disposed in the second dummy pixel area DMA2 surrounding the display area DPA and the first dummy pixel area DMA1. The dummy electrode lines RM1 and the first dummy electrode patterns RP1 may be disposed in the first area A1 and the third area A3 of the second dummy pixel area DMA2, and the second and third dummy electrode patterns RP2 and RP3 may be disposed in the second area A2.

The dummy electrode lines RM1 and the dummy electrode patterns RP1 to RP3, and the electrodes RME1 and RME2 disposed in the display area DPA and the first dummy pixel area DMA1 may be disposed on a same layer. The dummy electrode lines RM1 and the dummy electrode patterns RP1 to RP3 may be disposed directly on the via layer VIA, and the dummy electrode lines RM1, the dummy electrode patterns RP1 to RP3, and the electrodes RME1 and RME2 may include a same material. The dummy electrode lines RM1, the dummy electrode patterns RP1 to RP3, and the electrodes RME1 and RME2 may be formed together in a same process.

The dummy electrode lines RM1 may be disposed in the first area A1 and the third area A3 of the second dummy pixel area DMA2. The dummy electrode lines RM1, the second electrodes RME2 disposed in the pixels PX of the display area DPA, and the dummy pixels DPX of the first dummy pixel area DMA1 may have substantially a same shape. For example, each of the dummy electrode lines RM1 may include an electrode stem portion RM_S extending in the first direction DR1 and first and second electrode branch portions RM_B1 and RM_B2 branching from the electrode stem portion RM_S, bending in the second direction DR2 and extending in the first direction DR1. The structures of the electrode stem portion RM_S and the electrode branch portions RM_B1 and RM_B2 of each dummy electrode line RM1 are the same as those described above with reference to FIG. 5.

The electrode stem portions RM_S of the dummy electrode lines RM1 may be connected to the second electrodes RME2 of the pixels PX and the dummy pixels DPX. The electrode stem portions RM_S of the dummy electrode lines RM1 disposed in the first area A1 may be connected to the second electrodes RME2 of the dummy pixels DPX at a boundary between the first dummy pixel area DMA1 and the second dummy pixel area DMA2. The electrode stem portions RM_S of the dummy electrode lines RM1 disposed in the third area A3 may be connected to the second electrodes RME2 of the pixels PX at a boundary between the display area DPA and the second dummy pixel area DMA2. In the display device 10, the second electrodes RME2 and the first dummy electrode lines RM1 may extend in the first direction DR1 across the display area DPA and the dummy pixel areas DMA1 and DMA2. The first dummy electrode lines RM1 may be disposed in each of the first area A1 and the third area A3 of the second dummy pixel area DMA2.

A first dummy electrode line RM1 and a second electrode RME2 may be formed as substantially an integrated pattern. The integrated pattern may extend in the first direction DR1 and may be referred to as a second electrode RME2 in the display area DPA and the first dummy pixel area DMA1 and may be referred to as a first dummy electrode line RM1 in the second dummy pixel area DMA2. The dummy electrode lines RM1 may be electrically connected to the second voltage wirings VL2 through the second electrodes RME2 disposed in the pixels PX of the display area DPA and the dummy pixels DPX of the first dummy pixel area DMA1.

The first dummy electrode patterns RP1 may be disposed in the first area A1 and the third area A3 of the second dummy pixel area DMA2. The first dummy electrode patterns RP1, the first electrodes RME1 disposed in the pixels PX of the display area DPA, and the dummy pixels DPX of the first dummy pixel area DMA1 may have substantially a same shape. For example, the first dummy electrode patterns RP1 may extend in the first direction DR1 and may be disposed between the electrode branch portions RM_B1 and RM_B2 of the first dummy electrode lines RM1. In the first area A1 and the third area A3, the first dummy electrode patterns RP1 and the first dummy electrode lines RM1 may be alternately and repeatedly disposed in the second direction DR2.

The first dummy electrode patterns RP1 may be spaced apart from adjacent first electrodes RME1 of the first dummy pixel area DMA1 or adjacent first electrodes RME1 of the pixels PX of the display area DPA. The first dummy electrode patterns RP1 disposed in the first area A1 may be spaced apart from the first electrodes RME1 of the dummy pixels DPX in the first direction DR1 at the boundary between the first dummy pixel area DMA1 and the second dummy pixel area DMA2. The first dummy electrode patterns RP1 disposed in the third area A3 may be spaced apart from the first electrodes RME1 of the pixels PX in the first direction DR1 at the boundary between the display area DPA and the second dummy pixel area DMA2.

The first electrodes RME1 disposed in the display area DPA and the first dummy pixel area DMA1 may extend in the first direction DR1 and may be separated from other first electrodes RME1 or the wiring connection electrodes EP by the separation portions ROP1 and ROP2 in the sub-areas SA1 and SA2. For example, the first electrodes RME1 and the wiring connection electrodes EP spaced apart from each other in the first direction DR1 may be formed to be connected to each other and may be separated from each other in a subsequent process. On the other hand, the first dummy electrode patterns RP1 disposed in the second dummy pixel area DMA2 may be formed to be spaced apart from the first electrodes RME1 of the dummy pixels DPX and the pixels PX in the first direction DR1. The first dummy electrode patterns RP1 and the first electrodes RME1 may be spaced apart from each other in the first direction DR1 in the same manner that different first electrodes RME1 arranged in the first direction DR1 are spaced apart from each other in the first direction DR1, but a difference may lie in whether the separation portions ROP1 and ROP2 are formed between them. As described above, since the separation portions ROP1 and ROP2 are openings formed in the first insulating layer PAS1 and the second insulating layer PAS2, portions between the first dummy electrode patterns RP1 and the first electrodes RME1 may be covered by the first insulating layer PAS1.

According to an embodiment, the first dummy electrode patterns RP1 may be connected to the electrode branch portions RM_B1 and RM_B2 of the first dummy electrode lines RM1 adjacent to each other in the second direction DR2. Each of the first dummy electrode patterns RP1 may be integrally connected to the first electrode branch portion RM_B1 of a first dummy electrode line RM1 disposed on a left side which is a side in the second direction DR2 and may be spaced apart from the second electrode branch portion RM_B2 of a first dummy electrode line RM1 disposed on a right side which is the other side in the second direction DR2. The first dummy electrode patterns RP1 may be spaced apart from the first electrodes RME1 of the pixels PX or the dummy pixels DPX in the first direction DR1 but may be connected to the dummy electrode lines RM1 and may be electrically connected to the second voltage wirings VL2 through the dummy electrode lines RM1. The first dummy electrode patterns RP1 and the dummy electrode lines RM1 may not be electrically connected to the light emitting elements ED but may be electrically connected to the second voltage wirings VL2 to receive voltages while the display device 10 is being driven.

The dummy electrode lines RM1 disposed in the second dummy pixel area DMA2 may be divided into electrode rows RMR1 to RMR3 according to the arrangement of the electrode branch portions RM_B1 and RM_B2. In an electrode row RMR1, RMR2 or RMR3, a pair of the electrode branch portions RM_B1 and RM_B2 of each dummy electrode line RM1 may be arranged in the second direction DR2. For example, in the first area A1 of the second dummy pixel area DMA2 illustrated in FIG. 11, a first electrode row RMR1 of the dummy electrode lines RM1 and the first dummy electrode patterns RP1 are disposed as an electrode row. In the third area A3 of the second dummy pixel area DMA2 illustrated in FIG. 12, a second electrode row RMR2 and a third electrode row RMR3 of the dummy electrode lines RM1 and the first dummy electrode patterns RP1 are disposed as two electrode rows adjacent to each other in the first direction DR1. Accordingly, a width of the first area A1 of the second dummy pixel area DMA2 in the first direction DR1 may be smaller than a width of the third area A3 in the first direction DR1. The first dummy electrode patterns RP1 disposed in different electrode rows RMR1 to RMR3 may be integrally connected to each other, and a length of each first dummy electrode pattern RP1 may vary according to the number of adjacent electrode rows RMR1 to RMR3.

However, the disclosure is not limited thereto. Although FIGS. 11 and 12 illustrate an electrode row RMR1 and two electrode rows RMR2 and RMR3 as an example for better understanding, the number of the electrode rows RMR1 to RMR3 disposed in each of the first area A1 and the third area A3 is irrelevant to this example. According to an embodiment, one or more electrode rows RMR1 to RMR3 may be disposed in each of the first area A1 and the third area A3.

The lengths of the dummy electrode lines RM1 and the first dummy electrode patterns RP1 disposed in the second dummy pixel area DMA2 may vary according to the number of the electrode rows RMR1 to RMR3 disposed in the second dummy pixel area DMA2. In the first area A1, each dummy electrode line RM1 may include a pair of the electrode branch portions RM_B1 and RM_B2 to form a first electrode row RMR1. On the other hand, in the third area A3, each dummy electrode line RM1 may include two pairs of the electrode branch portions RM_B1 and RM_B2 to form the second electrode row RMR2 and the third electrode row RMR3 in which different pairs of the electrode branch portions RM_B1 and RM_B2 spaced apart from each other in the first direction DR1 are arranged in the second direction DR2. Accordingly, the lengths of the dummy electrode lines RM1 and the first dummy electrode patterns RP1 measured in the first direction DR1 in the first area A1 may be smaller than the lengths of the dummy electrode lines RM1 and the first dummy electrode patterns RP1 measured in the first direction DR1 in the third area A3. However, the disclosure is not limited thereto.

The second dummy electrode patterns RP2 and the third dummy electrode patterns RP3 may be disposed in the second area A2 of the second dummy pixel area DMA2. The second dummy electrode patterns RP2 may be disposed in a portion of the second area A2 which is parallel to the first area A1 or the third area A3 in the second direction DR2, and the third dummy electrode patterns RP3 may be disposed in a portion of the second area A2 which is parallel to the first dummy pixel area DMA1 in the second direction DR2. The second dummy electrode patterns RP2 and the third dummy electrode patterns RP3 may be electrode patterns disposed in an outermost portion of the display device 10 in the second direction DR2.

The second dummy electrode patterns RP2 and the third dummy electrode patterns RP3 may have a substantially similar shape to the first electrodes RME1. The second dummy electrode patterns RP2 and the third dummy electrode patterns RP3 may extend in the first direction DR1 and may be spaced apart from each other in the first direction DR1. Uppermost and lowermost sides of the second dummy pixel area DMA2 are portions parallel to the first area A1 and the third area A3 of the second dummy pixel area DMA2 in the second direction DR2, and at least one second dummy electrode pattern RP2 may be disposed in these portions. The second dummy electrode patterns RP2 may be disposed parallel to the first dummy electrode patterns RP1 in the second direction DR2. A middle portion of the second dummy pixel area DMA2 is a portion parallel to the first dummy pixel area DMA1 in the second direction DR2, and third dummy electrode patterns RP3 may be disposed in this portion. The third dummy electrode patterns RP3 may be disposed parallel to the first electrodes RME1 of the pixels PX and the dummy pixels DPX in the second direction DR2.

Similar to the first dummy electrode patterns RP1, each of the second dummy electrode patterns RP2 and the third dummy electrode patterns RP3 may be connected to a dummy electrode line RM1 or a second electrode RME2. Each of the second dummy electrode patterns RP2 may be connected to the electrode branch portion RM_B1 or RM_B2 of a dummy electrode line RM1 disposed in an outermost portion of the first area A1 or the third area A3. Each of the third dummy electrode patterns RP3 may be connected to a second electrode RME2 of a dummy pixel DPX disposed in an outermost portion of the first dummy pixel area DMA1 in the second direction DR2. Each of the third dummy electrode patterns RP3 may be connected to the electrode branch portion RM_B1 or RM_B2 of the second electrode RME2. Accordingly, the second dummy electrode patterns RP2 and the third dummy electrode patterns RP3 may also be electrically connected to the second voltage wirings VL2.

FIG. 12 illustrates that the second area A2 including the second dummy electrode patterns RP2 and the third dummy electrode patterns RP3 is adjacent to the first dummy pixel area DMA1 disposed on sides of the display area DPA in the second direction DR2. For example, the third dummy electrode patterns RP3 are connected to the second electrodes RME2 of the dummy pixels DPX. However, the disclosure is not limited thereto. In some embodiments, several pairs of the dummy electrode line RM1 and the first dummy electrode pattern RP1 may be disposed between the first dummy pixel area DMA1 disposed on sides of the display area DPA in the second direction DR2 and the third dummy electrode patterns RP3. A fourth area of the second dummy pixel area DMA2 which extends in the first direction DR1 may be disposed between the first dummy pixel area DMA1 and the second area A2.

In the pixels PX of the display area DPA, the electrodes RME1 and RME2 may be spaced apart from each other. As described above, the distance between the first and second electrodes RME1 and RME2 in the emission area EMA may be smaller than the length of each light emitting element ED. Since the length of each light emitting element ED is relatively small, the distance between the first and second electrodes RME1 and RME2 may also be relatively small. In case that the electrodes RME1 and RME2 are formed in the manufacturing process of the display device 10, if a margin of an exposure process differs according to position in the display area DPA, the distance between the electrodes RME1 and RME2 may be different in some pixels PX. To prevent this, the display device 10 according to the embodiment may include the dummy pixels DPX, the dummy electrode lines RM1 and the dummy electrode patterns RP1 to RP3 disposed around the display area DPA and having a similar structure to the electrodes RME1 and RME2 of the pixels PX disposed in the display area DPA. The electrodes RME1 and RME2, the dummy electrode lines RM1 and the dummy electrode patterns RP1 to RP3 of the dummy pixels DPX, and the electrodes RME1 and RME2 of the display area DPA may be formed in a same process. Since the electrodes RME1 and RME2, the dummy electrode lines RM1, and the dummy electrode patterns RP1 to RP3 are formed in an area larger than the display area DPA, a difference in the margin of the exposure process may be reduced regardless of position in the display area DPA, and the distance between the electrodes RME1 and RME2 at least in the pixels PX disposed in the display area DPA may be maintained constant.

According to an embodiment, in the display device 10, pixel circuits disposed in the pixels PX of the display area DPA may be disposed in the first dummy pixel area DMA1 but may not be disposed in the second dummy pixel area DMA2.

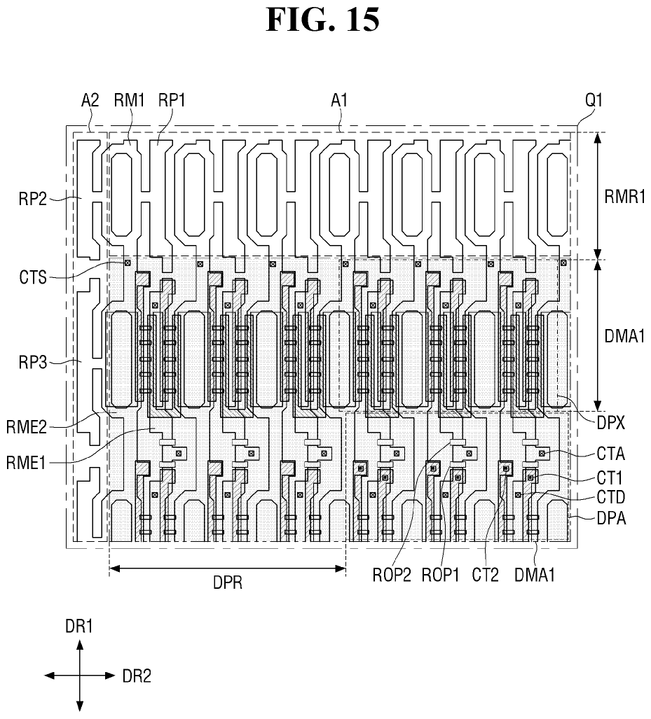

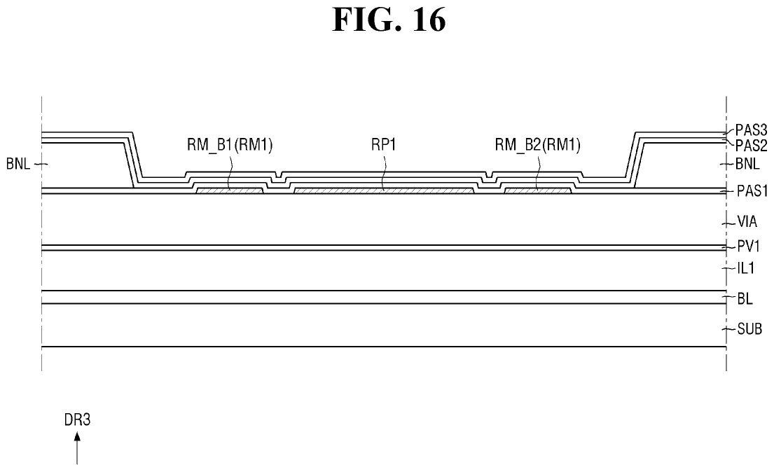

FIG. 15 is a schematic plan view illustrating a portion in which pixel circuit parts are disposed in the display area DPA and a dummy pixel area of the display device 10 according to the embodiment. FIG. 16 is a schematic cross-sectional view of the first area A1 of the second dummy pixel area DMA2 according to an embodiment.

Referring to FIGS. 15 and 16, the display device 10 may include the pixel circuit parts to which the subpixels SPXn of the pixels PX disposed in the display area DPA are connected. As described above with reference to FIGS. 3 and 4, each of the pixel circuit parts may include transistors T1 to T3, voltage wirings VL1 and VL2, scan lines SL1 and SL2, a data line DTL, and an initialization voltage wiring VIL. The transistors T1 to T3 and other wirings may be formed as conductive patterns or wirings of the first to third conductive layers described above with reference to FIG. 6. As illustrated in FIG. 6, transistors T1 and T2 and voltage wirings VL1 and VL2 formed as the conductive patterns or voltage wirings of the first to third conductive layers may be disposed in the subpixels SPXn of the pixels PX disposed in the display area DPA.

The conductive patterns and wirings of the first to third conductive layers constituting the pixel circuit parts may be disposed in the display area DPA and the first dummy pixel area DMA1 but may not be disposed in the second dummy pixel area DMA2. The pixels PX of the display area DPA and the dummy pixels DPX of the first dummy pixel area DMA1 may be connected to the pixel circuit parts formed as the conductive patterns and wirings of the first to third conductive layers disposed under the pixels PX and the dummy pixels DPX. For example, the pixels PX of the display area DPA and the dummy pixels DPX of the first dummy pixel area DMA1 may overlap the conductive patterns and wirings of the first to third conductive layers in the thickness direction. The first electrodes RME1 of the pixels PX of the display area DPA and the dummy pixels DPX of the first dummy pixel area DMA1 may be electrically connected to the first transistors T1 and the first voltage wirings VL1, and the second electrodes RME2 may be electrically connected to the second voltage wirings VL2.

On the other hand, the conductive patterns and wirings of the first to third conductive layers constituting the pixel circuit parts may not be disposed in the second dummy pixel area DMA2. As illustrated in FIG. 16, the conductive patterns and wirings of the first to third conductive layers may not be disposed under the via layer VIA in the second dummy pixel area DMA2. The dummy electrode lines RM1 and the dummy electrode patterns RP1 to RP3 disposed in the second dummy pixel area DMA2 may not overlap the conductive patterns and wirings of the first to third conductive layers in the thickness direction. However, the dummy electrode lines RM1 may extend in the first direction DR1 to be integrated with the second electrodes RME2 of the dummy pixels DPX and may be electrically connected to the second voltage wirings VL2. The dummy electrode patterns RP1 to RP3 may be electrically connected to adjacent dummy electrode lines RM1 or adjacent second electrodes RME2 and thus may be electrically connected to the second voltage wirings VL2.

The first to third insulating layers PAS1 to PAS3 and the bank layer BNL disposed on the via layer VIA may be disposed in the second dummy pixel area DMA2 as well. The first insulating layer PAS1 may be disposed on the dummy electrode lines RM1 and the dummy electrode patterns RP1 to RP3 of the second dummy pixel area DMA2, and the bank layer BNL, the second insulating layer PAS2 and the third insulating layer PAS3 may be disposed on the first insulating layer PAS1. However, unlike in the pixels PX of the display area DPA, the light emitting elements ED may not be disposed in the second dummy pixel area DMA2.

Although not illustrated in the drawings, the bank layer BNL may also be disposed in a grid pattern extending in the first direction DR1 and the second direction DR2 in the second dummy pixel area DMA2, as in the display area DPA. The bank layer BNL may surround a specific area so as not to overlap the electrode branch portions RM_B1 and RM_B2 of a dummy electrode line RM1 and a portion of a first dummy electrode pattern RP1 in the second dummy pixel area DMA2. However, the disclosure is not limited thereto.

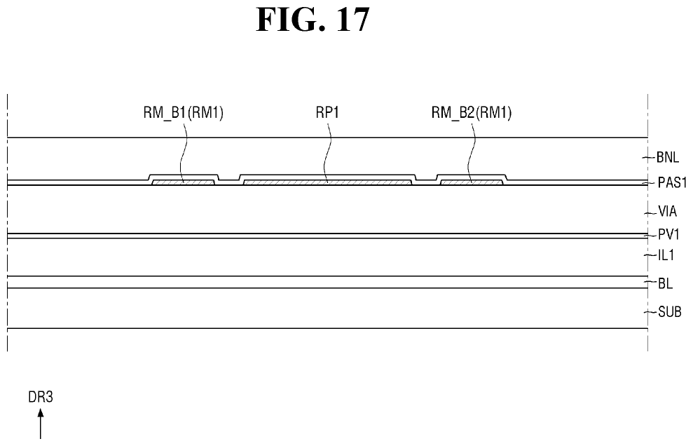

FIG. 17 is a schematic cross-sectional view of a first area of a second dummy pixel area DMA2 according to an embodiment.

Referring to FIG. 17, in a display device 10 according to an embodiment, the second dummy pixel area DMA2 may be completely covered by a bank layer BNL. In the second dummy pixel area DMA2, dummy electrode lines RM1 and dummy electrode patterns RP1 to RP3 may be disposed on a via layer VIA and may be completely covered by a first insulating layer PAS1 and the bank layer BNL. A second insulating layer PAS2 and a third insulating layer PAS3 may not be disposed in the second dummy pixel area DMA2.

While the dummy electrode lines RM1 and the dummy electrode patterns RP1 to RP3 are disposed in the second dummy pixel area DMA2 to maintain a constant distance between electrodes RME1 and RME2 of a display area DPA, light emitting elements ED may not be disposed in the second dummy pixel area DMA2. Accordingly, the bank layer BNL may not surround a specific area, such as an emission area EMA, in the second dummy pixel area DMA2, unlike in the structure of pixels PX of the display area DPA. Therefore, in the second dummy pixel area DMA2, only the first insulating layer PAS1 and the bank layer BNL that completely cover the dummy electrode lines RM1 and the dummy electrode patterns RP1 to RP3 may be disposed in addition to the dummy electrode lines RM1 and the dummy electrode patterns RP1 to RP3.

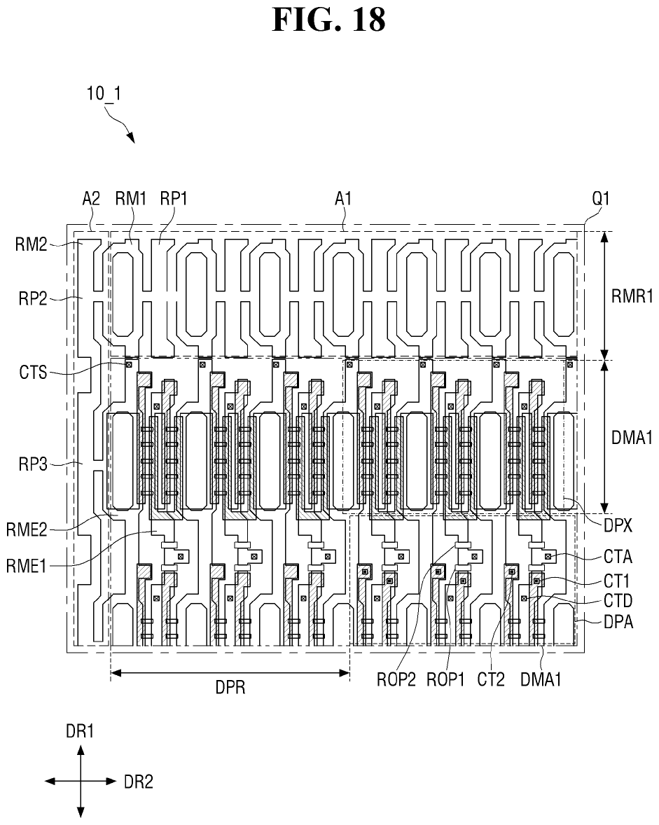

FIG. 18 is a schematic plan view illustrating dummy electrode lines RM1 and RM2 in a dummy pixel area of a display device 10_1 according to an embodiment.

Referring to FIG. 18, in the display device 10_1 according to the embodiment, shapes and structures of dummy electrode lines RM1 and RM2 and first dummy electrode patterns RP1 disposed in a second dummy pixel area DMA2 may be different from those of the above-described embodiments.

The dummy electrode lines RM1 and RM2 may include first dummy electrode lines RM1 disposed in a first area A1 and a third area A3 (not illustrated) and a second dummy electrode line RM2 disposed in a second area A2. The first dummy electrode lines RM1 and those of the embodiment of FIGS. 11 and 12 may have substantially a same shape, but the first dummy electrode lines RM1 may be spaced apart from second electrodes RME2 of dummy pixels DPX. Each of the first dummy electrode lines RM1 may generally extend in the first direction DR1 and may include electrode branch portions RM_B1 and RM_B2 branched from each other. However, in the first dummy electrode lines RM1 disposed in an area closest to the dummy pixels DPX or pixels PX, electrode stem portions RM_S may be spaced apart from the second electrodes RME2 without being integrated with the second electrodes RME2. This may be the same as the first dummy electrode patterns RP1 being spaced apart from first electrodes RME1.

The second dummy electrode line RM2 may be disposed in the second area A2 and may extend in the first direction DR1. The second dummy electrode line RM2 may be disposed in an outermost portion on sides of the display device 10 in the second direction DR2. The second dummy electrode line RM2 may be disposed on a left side or a right side of a first dummy electrode line RM1 and a second electrode RME2 disposed in an outermost portion on sides of a first dummy pixel area DMA1 and a display area DPA in the second direction DR2.

The first dummy electrode patterns RP1 may be disposed between the first dummy electrode lines RM1 in the first area A1 and the third area A3 of the second dummy pixel area DMA2. In the first area A1 and the third area A3, the first dummy electrode lines RM1 and the first dummy electrode patterns RP1 may be alternately disposed in the second direction DR2.

According to an embodiment, the first dummy electrode lines RM1, the second dummy electrode line RM2, and the first dummy electrode patterns RP1 of the second dummy pixel area DMA2 may be integrally connected to each other, and the second dummy electrode line RM2 may be integrally connected to the second electrodes RME2 of the dummy pixels DPX. In the first area A1 and the third area A3, each of the first dummy electrode patterns RP1 may be connected to the electrode branch portions RM_B1 and RM_B2 of the first dummy electrode lines RM1 disposed on sides in the second direction DR2. In the first area A1 and the third area A3, a first dummy electrode line RM1 disposed in an outermost portion on sides in the second direction DR2 may be connected to the second dummy electrode line RM2 disposed in the second area A2. The second dummy electrode line RM2 may extend in the first direction DR1 and may be integrally connected to the second electrodes RME2 of the dummy pixels DPX. A connection portion between the second dummy electrode line RM2 and a second electrode RME2 may be disposed in each row of the dummy pixels DPX and the pixels PX in the first dummy pixel area DMA1 and the display area DPA.

The embodiment is different from the above-described embodiments in that the first dummy electrode lines RM1 disposed in the first area A1 and the third area A3 are spaced apart from the second electrodes RME2 of the dummy pixels DPX or the pixels PX adjacent to each other in the first direction DR1 and are electrically connected to the second electrodes RME2 through the second dummy electrode line RM2 disposed in the second area A2.

A display device according to an embodiment may include a dummy pixel area in which dummy pixels having a similar structure to pixels and dummy electrode lines and dummy electrode patterns having a similar structure to electrodes of the pixels are disposed. The display device may reduce a difference in exposure margin that may occur in case that electrodes disposed in a display area are formed and may maintain a uniform distance between the electrodes of the display area regardless of position.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display area in which pixels are disposed, each of the pixels comprising:
a first electrode and a second electrode extending in a first direction and spaced apart from each other in a second direction; and
light emitting elements disposed on the first electrode and the second electrode;
a first dummy pixel area disposed outside the display area and in which dummy pixels are disposed, each of the dummy pixels comprising the first electrode, the second electrode and the light emitting elements; and
a second dummy pixel area surrounding the display area and the first dummy pixel area and in which dummy electrode lines and dummy electrode patterns are disposed, wherein
the dummy electrode lines extend in the first direction, are spaced apart from each other in the second direction, and are electrically connected to the second electrodes of the dummy pixels, and
the dummy electrode patterns extend in the first direction, are disposed between the dummy electrode lines, and are spaced apart from the first electrodes of the dummy pixels in the first direction.

2. The display device of claim 1, wherein
the second dummy pixel area comprises:
a first area disposed on a side of the display area in the first direction;
a second area disposed on each of sides of the display area in the second direction; and
a third area disposed on another side of the display area in the first direction, and
the first dummy electrode lines and the first dummy electrode patterns are disposed in the first area and the third area.

3. The display device of claim 2, wherein each of the first dummy electrode patterns disposed in the first area and the third area is electrically connected to any adjacent one of the dummy electrode lines.

4. The display device of claim 2, wherein the dummy electrode lines disposed in the third area are directly connected to the second electrodes disposed in the pixels of the display area.

5. The display device of claim 2, wherein the dummy electrode patterns comprise:
second dummy electrode patterns disposed in the second area on sides of the first area and the third area in the second direction; and
third dummy patterns disposed in the second area on sides of the display area in the second direction and spaced apart from each other in the first direction.

6. The display device of claim 5, wherein the third dummy electrode patterns are respectively electrically connected to the second electrodes of the dummy pixels disposed in the first dummy pixel area.

7. The display device of claim 5, wherein the second dummy electrode patterns are respectively electrically connected to the dummy electrode lines disposed in outermost portions of the first area and the third area.

8. The display device of claim 2, wherein the first dummy pixel area is disposed between the display area and the first area and the second area of the second dummy pixel area.

9. The display device of claim 2, wherein the third area of the second dummy pixel area is in contact with the display area.

10. The display device of claim 2, wherein lengths of the dummy electrode lines and the first dummy electrode patterns in the first direction in the third area are greater than lengths of the dummy electrode lines and the first dummy electrode patterns in the first direction in the first area.

11. The display device of claim 1, wherein
the second electrodes disposed in the first dummy pixel area are directly connected to the second electrodes of the pixels disposed in the display area, and
the first electrodes disposed in the first dummy pixel area are spaced apart from the first electrodes of the pixels disposed in the display area.

12. The display device of claim 1, wherein the light emitting elements are not disposed in the second dummy pixel area.

13. The display device of claim 1, comprising:
a first connection electrode disposed on the first electrode of each of the pixels and the dummy pixels and electrically contacting the light emitting elements; and
a second connection electrode disposed on the second electrode of each of the pixels and the dummy pixels and electrically contacting the light emitting elements,
wherein the first connection electrode and the second connection electrode of each pixel electrically contact the first electrode and the second electrode, respectively.

14. The display device of claim 13, wherein the first connection electrode and the second connection electrode disposed in each of the dummy pixels do not electrically contact the first electrode and the second electrode, respectively.

15. The display device of claim 13, wherein the first connection electrode and the second connection electrode are not disposed in the second dummy pixel area.

16. The display device of claim 1, wherein the first and second electrodes, the dummy electrode lines, and the dummy electrode patterns are disposed on a same layer.

17. A display device comprising:
a display area in which pixels are disposed, each of the pixels comprising:
a first electrode and a second electrode extending in a first direction and spaced apart from each other in a second direction; and
light emitting elements disposed on the first electrode and the second electrode;
a first dummy pixel area disposed outside the display area and in which dummy pixels are disposed, each of the dummy pixels comprising:
the first electrode;
the second electrode; and
the light emitting elements; and
a second dummy pixel area surrounding the display area and the first dummy pixel area and in which dummy electrode lines and dummy electrode patterns are disposed, wherein
the second dummy pixel area comprises:
a first area disposed on a side of the display area in the first direction;
a second area disposed on each of sides of the display area in the second direction; and
a third area disposed on another side of the display area in the first direction, the dummy electrode lines comprise:
first dummy electrode lines disposed in the first area and the third area; and
a second dummy electrode line disposed in the second area, and
the dummy electrode patterns comprise a first dummy electrode pattern disposed between the first dummy electrode lines in the first area and the third area and electrically connected to each of adjacent ones of the first dummy electrode lines.

18. The display device of claim 17, wherein
the first dummy electrode lines are spaced apart from the second electrodes of the dummy pixels in the first direction, and
the second dummy electrode line is directly connected to the second electrodes of the dummy pixels disposed in an outermost portion of the first dummy pixel area in the second direction.

19. The display device of claim 18, wherein the second dummy electrode line is directly connected to the first dummy electrode lines disposed in outermost portions of the first area and the third area in the second direction.

20. The display device of claim 17, wherein the light emitting elements are not disposed in the second dummy pixel area.
